(19) United States
(12) Patent Application Publication
(10) Pub. No.: US 2026/0101556 A1
(43) Pub. Date: Apr. 9, 2026

(54) NITRIDE SEMICONDUCTOR DEVICE

(71) Applicant: FUJI ELECTRIC CO., LTD., Kawasaki-shi (JP)

(72) Inventor: Katsunori UENO, Matsumoto-city (JP)

(73) Assignee: FUJI ELECTRIC CO., LTD., Kawasaki-shi (JP)

(21) Appl. No.: 19/314,124

(22) Filed: Aug. 29, 2025

(30) Foreign Application Priority Data
Oct. 4, 2024 (JP) 2024-174914

(51) Int. Cl. H10D 62/815; H10D 12/00; H10D 30/01; H10D 30/66; H10D 62/10; H10D 62/60; H10D 62/85; H10D 62/854

(52) U.S. Cl. CPC H10D 62/8171; H10D 12/441; H10D 30/66; H10D 62/102; H10D 62/124; H10D 62/126; H10D 62/60; H10D 62/8503; H10D 62/854; H10D 30/0291

(57) ABSTRACT

A transistor having normally-off characteristics included in the nitride semiconductor device includes a gate insulating film provided on a first surface side of the nitride semiconductor substrate, a gate electrode provided on the gate insulating film, a p-type layer located to be opposed to the gate electrode with the gate insulating film interposed, and an n-type layer located to be opposed to the gate electrode with the p-type layer interposed so as to be in contact with the p-type layer. A Mg concentration in the p-type layer is 1×10¹⁸ cm⁻³ or higher and 1×10²⁰ cm⁻³ or lower. The inequalities (1) and (2) are fulfilled, where an effective acceptor concentration of the p-type layer is Np (cm⁻³), a thickness of the p-type layer is dp (nm), an effective donor concentration of the n-type layer is Nn (cm⁻³), and a thickness of the n-type layer is dn (nm).

### CROSS-REFERENCE TO RELATED APPLICATION

This application claims benefit of priority under 35 USC 119 based on Japanese Patent Application No. 2024-174914 filed on Oct. 4, 2024, the entire contents of which are incorporated by reference herein.

### BACKGROUND OF THE INVENTION

### 1. Field of the Invention

The present disclosure relates to nitride semiconductor devices.

### 2. Description of the Related Art

JP2003-31802A discloses a field effect transistor provided in a SiC substrate. A channel region in the field effect transistor includes a p-type gate semiconductor region, an n-type buried channel region, and a p-type body semiconductor region.

MRS BULLETIN, VOLUME 40, May 2015, www.mrs.org/bulletin, 425-430 discloses a DioMOS provided in a SiC substrate. The DioMOS includes an n-type delta-doped channel region on the front surface side.

### SUMMARY OF THE INVENTION

MOSFETs conventionally provided in a GaN substrate are provided with a large number of hole traps at an interface between the GaN substrate and a gate insulating film. These hole traps can be inactivated such that Mg is introduced at a high concentration into the interface. The introduction of Mg serving as an acceptor at a high concentration, however, excessively increases a threshold of a MOSFET, which is not applicable.

In view of the foregoing problems, the present disclosure provides a nitride semiconductor device having a configuration enabling introduction of Mg at a high concentration while decreasing a threshold to a low level.

### Solution to Problem

In order to solve the problems described above, a nitride semiconductor device according to an aspect of the present disclosure includes a nitride semiconductor substrate, and a transistor having a normally-off characteristic provided in the nitride semiconductor substrate. The transistor includes a gate insulating film provided on a first surface side of the nitride semiconductor substrate, a gate electrode provided on the gate insulating film, a p-type layer located to be opposed to the gate electrode with the gate insulating film interposed, and an n-type layer located to be opposed to the gate electrode with the p-type layer interposed so as to be in contact with the p-type layer. A Mg concentration in the p-type layer is in a range of 1×10¹⁸ cm⁻³ or higher and 1×10²⁰ cm⁻³ or lower. The following inequations (1) and (2) are fulfilled, where an effective acceptor concentration of the p-type layer in which a donor concentration is canceled out of an acceptor concentration is Np (cm⁻³) and a thickness of the p-type layer is dp (nm), and an effective donor concentration of the n-type layer in which an acceptor concentration is canceled out of a donor concentration is Nn (cm⁻³) and a thickness of the n-type layer is dn (nm):

$$[ Math . 1 ]$$

$$3 nm < {d}_{n} ( nm ) < 1.16 \times {10}^{11} \sqrt{\frac{{N}_{p}}{( {N}_{n} + {N}_{p} ) {N}_{n}}} \qquad ( 1 )$$

$$3 nm < {d}_{p} ( nm ) < 5.78 \times {10}^{10} \sqrt{\frac{{N}_{n}}{( {N}_{n} + {N}_{p} ) {N}_{p}}} \qquad ( 2 )$$

### BRIEF DESCRIPTION OF THE DRAWINGS

FIG. 1 is a cross-sectional view illustrating a configuration example of a lateral MOSFET having normally-off characteristics according to an embodiment of the present disclosure;

FIG. 2 is an enlarged cross-sectional view illustrating a p⁺-type well region, an n⁺-type layer, and a p⁺-type layer;

FIG. 3 is a graph showing simulation results obtained by the inventor of the present disclosure, regarding a relation between an effective acceptor concentration of the p⁺-type layer and a thickness of the n⁺-type layer;

FIG. 4 is a graph showing simulation results obtained by the inventor of the present disclosure, regarding a relation between the effective acceptor concentration of the p⁺-type layer and a thickness of the p⁺-type layer;

FIG. 5 is a cross-sectional view illustrating a modified example of the lateral MOSFET according to Embodiment 1 of the present disclosure;

FIG. 6 is a cross-sectional view illustrating a configuration example of a vertical MOSFET having normally-off characteristics according to Embodiment 2 of the present disclosure;

FIG. 7 is a cross-sectional view illustrating a modified example of the vertical MOSFET according to Embodiment 2 of the present disclosure;

FIG. 8 is a cross-sectional view illustrating a configuration example of a vertical MOSFET having normally-off characteristics according to Embodiment 3 of the present disclosure;

FIG. 9 is a cross-sectional view illustrating a modified example of the vertical MOSFET according to Embodiment 3 of the present disclosure;

FIG. 10 is a cross-sectional view illustrating a configuration example of a vertical MOSFET having normally-off characteristics according to Embodiment 4 of the present disclosure;

FIG. 11 is a cross-sectional view illustrating the configuration example of the vertical MOSFET according to Embodiment 4 of the present disclosure;

FIG. 12 is a plan view illustrating the configuration example of the vertical MOSFET according to Embodiment 4 of the present disclosure;

FIG. 13 is a cross-sectional view illustrating a modified example of the vertical MOSFET according to Embodiment 4 of the present disclosure;

FIG. 14A is a cross-sectional view illustrating a sequential process of a method of manufacturing a vertical MOSFET according to Embodiment 5 of the present disclosure;

FIG. 14B is a cross-sectional view illustrating the sequential process of the method of manufacturing the vertical MOSFET according to Embodiment 5 of the present disclosure;

FIG. 14C is a cross-sectional view illustrating the sequential process of the method of manufacturing the vertical MOSFET according to Embodiment 5 of the present disclosure;

FIG. 14D is a cross-sectional view illustrating the sequential process of the method of manufacturing the vertical MOSFET according to Embodiment 5 of the present disclosure;

FIG. 14E is a cross-sectional view illustrating the sequential process of the method of manufacturing the vertical MOSFET according to Embodiment 5 of the present disclosure;

FIG. 14F is a cross-sectional view illustrating the sequential process of the method of manufacturing the vertical MOSFET according to Embodiment 5 of the present disclosure;

FIG. 15 is a graph showing modified example 1 of the manufacturing method according to Embodiment 5;

FIG. 16 is a graph showing modified example 2 of the manufacturing method according to Embodiment 5;

FIG. 17A is a cross-sectional view illustrating a sequential process of a method of manufacturing a vertical MOSFET according to Embodiment 6 of the present disclosure;

FIG. 17B is a cross-sectional view illustrating the sequential process of the method of manufacturing the vertical MOSFET according to Embodiment 6 of the present disclosure;

FIG. 17C is a cross-sectional view illustrating the sequential process of the method of manufacturing the vertical MOSFET according to Embodiment 6 of the present disclosure;

FIG. 17D is a cross-sectional view illustrating the sequential process of the method of manufacturing the vertical MOSFET according to Embodiment 6 of the present disclosure;

FIG. 17E is a cross-sectional view illustrating the sequential process of the method of manufacturing the vertical MOSFET according to Embodiment 6 of the present disclosure;

FIG. 17F is a cross-sectional view illustrating the sequential process of the method of manufacturing the vertical MOSFET according to Embodiment 6 of the present disclosure;

FIG. 18 is a cross-sectional view illustrating a configuration example of an IGBT having normally-off characteristics according to Embodiment 7 of the present disclosure; and

FIG. 19 is a cross-sectional view illustrating a modified example of the IGBT according to Embodiment 7 of the present disclosure.

### DETAILED DESCRIPTION

Some embodiments according to the present disclosure are descried below.

In the following explanations regarding the drawings, the same or similar components are denoted by the same or similar reference numerals. The drawings are illustrated schematically, and relationships between thicknesses and planar dimensions, and proportions of the thicknesses of the respective members are not drawn to scale. The specific thicknesses and dimensions therefore should be determined in accordance with the explanations below. It should also be understood that the relationships or proportions of the dimensions between the drawings can differ from each other.

The following explanations may refer to the respective directions as an X-axis direction, a Y-axis direction, and a Z-axis direction. For example, the X-axis direction and the Y-axis direction are each a direction parallel to a top surface 10a of a GaN substrate 10 described below. The Z-axis direction is a direction orthogonal to the top surface 10a of the GaN substrate 10. The X-axis direction, the Y-axis direction, and the Z-axis are perpendicular to each other.

In the following explanations, the positive direction in the Z-axis may be referred to as an “upper side”, and the negative direction in the Z-axis may be referred to as a “lower side”. The definitions of the “upper side” and the “lower side” do not necessarily mean the directions vertical to the ground. In other words, the respective directions of the “upper side” and the “lower side” are not limited to the gravity direction. The definitions regarding the “upper side” and the “lower side” are used only for illustration purposes to define the relative positional relationship among regions, layers, films, and a substrate, which do not limit the technical idea of the present disclosure. For example, when the observing direction of the sheet is changed by 180 degrees, the definitions of the “upper side” and the “lower side” shall be reversed.

In the following explanations, the signs “+” and “−” added to the signs “p” and “n” used for semiconductor regions signify that the respective semiconductor regions have either a higher impurity concentration or a lower impurity concentration than other semiconductor regions without the sign “+” or “−” added. It should be understood that the respective semiconductor regions to which the same sign “p” (or the same sign “n”) is added do not necessarily or strictly have the same impurity concentration.

### Embodiment 1

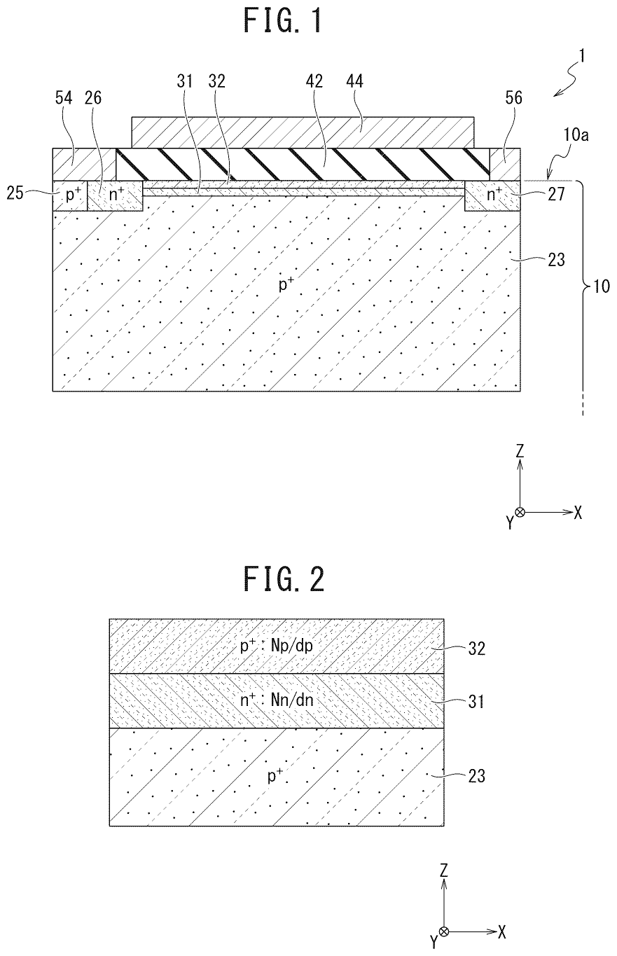

FIG. 1 is a cross-sectional view illustrating a configuration example of a lateral MOSFET 1 having normally-off characteristics according to an embodiment of the present disclosure (an example of a “transistor” according to the present disclosure). The term “normally-off characteristics” refers to a state in which a drain current does not flow through with no channels present when a voltage is not applied to a gate electrode. As illustrated in FIG. 1, the lateral MOSFET 1 is provided in a gallium nitride substrate (an example of a “nitride semiconductor” according to the present disclosure; referred to below as a “GaN substrate”) 10. The lateral MOSFET 1 includes a gate insulating film 42 provided on a front surface 10a (an example of a “first surface” of the present disclosure”) side of the GaN substrate 10, a gate electrode 44 provided on the gate insulating film 42, a well region 23 of p⁺-type provided in the GaN substrate 10, a source region 26 and a drain region 27 of n⁺-type provided adjacent to the front surface of the well region 23 under both sides of the gate electrode 44, a contact region 25 of p⁺-type provided adjacent to the front surface 10a of the GaN substrate 10 so as to be in contact with the well region 23, a source electrode 54 provided on the front surface 10a side of the GaN substrate 10 so as to be in contact with the source region 26 and the contact region 25, and a drain electrode 56 provided on the front surface 10a side of the GaN substrate 10 so as to be in contact with the drain region 27. The respective front surfaces of the well region 23, the contact region 25, the source region 26, and the drain region 27 conform to the front surface 10a of the GaN substrate 10.

The GaN substrate 10 as used herein is a GaN single-crystal substrate, which is a substrate of n-type, for example. The GaN substrate 10 has the front surface 10a and a rear surface located on the opposite side of the front surface 10a. The GaN substrate 10 is a low-dislocation free-standing GaN substrate having a threading dislocation density of less than 1×10⁷ cm⁻², for example.

A donor element (n-type impurities) included in the GaN substrate 10 may be at least one of silicon (Si), germanium (Ge), and oxygen (O). An acceptor element (p-type impurities) included in the GaN substrate 10 may be at least one of magnesium (Mg), calcium (Ca), beryllium (Be), and zinc (Zn).

The use of the low-dislocation free-standing GaN substrate as the GaN substrate 10 can minimize a current leakage from a power device having a large area regardless of whether to be formed in the GaN substrate 10. This can contribute to high-yield-rate manufacture of power devices. In addition, the use of such a GaN substrate can avoid a deep diffusion of implanted impurity ions along the dislocation during heat treatment executed in a process of manufacturing the lateral MOSFET 1.

The GaN substrate 10 may include a GaN single-crystal substrate and a GaN layer having single crystals epitaxially grown on the GaN single-crystal substrate. In such a case, the GaN single-crystal substrate may be either n⁺-type or n-type, and the GaN layer may be either n-type or n-type. The front surface 10a of the GaN substrate 10 may be a c-plane (a Ga plane) that is a polar surface, or may be an m-plane that is a non-polar surface.

The lateral MOSFET 1 includes semiconductor material of GaN, which may include either one or both of aluminum (Al) and indium (In). The semiconductor material may be mixed-crystal semiconductor having a slight amount of Al and In, which is AlxInyGa1-x-yN (0≤x<1, 0≤y<1). The present disclosure illustrates the case of including GaN in which AlxInyGa1-x-yN fulfills x=y=0.

The p⁺-type well region 23 is provided to extend from the front surface 10a of the GaN substrate 10 in the depth direction (in the direction opposite to the arrow of the Z-axis, for example). The well region 23 is provided such that an acceptor element (p-type impurity ions) is implanted from the front surface 10a of the GaN substrate 10 into a predetermined depth and is then subjected to heat treatment so as to be activated. Alternatively, the p⁺-type well region 23 may be formed either on the n-type GaN single-crystal substrate or on the n-type GaN layer included in the GaN substrate 10 by an epitaxial growth method.

The contact region 25 is provided such that an acceptor element is implanted from the front surface of the well region 23 into a predetermined depth and is then subjected to heat treatment so as to be activated. The contact region 25 is the p⁺-type region, and has a higher concentration of the acceptor element than the well region 23. The contact region 25 may have the same concentration of the acceptor element as the well region 23. In such a case, the contact region 25 may be a part of the well region 23 formed simultaneously with the well region 23 in the same process. The well region 23 and the contact region 25 each include at least either Mg or Be as the acceptor element.

The well region 23 and the contact region 25 each include Mg as the acceptor element, for example. The concentration of Mg included in the well region 23 is in a range of 1×10¹⁷ cm⁻³ or higher and 1×10²⁰ cm⁻³ or lower, preferably in a range of 1×10¹⁹ cm⁻³ or higher and 1×10²⁰ cm⁻³ or lower, and can be 1×10¹⁹ cm⁻³, for example. The concentration of Mg included in the contact region 25 is in a range of 1×10¹⁸ cm⁻³ or higher and 2×10²⁰ cm⁻³ or lower.

The source region 26 and the drain region 27 are each provided such that a donor element (n-type impurity ions) is implanted from the front surface 10a of the well region 23 into a predetermined depth and is then subjected to heat treatment so as to be activated. The source region 26 and the drain region 27 are each the n⁺-type region, and have the common concentration of the donor element. The source region 26 and the drain region 27 are formed simultaneously with each other in the same process. The source region 26 and the drain region 27 each include at least one of Si, Ge, and O as the donor element. The source region 26 and the drain region 27 include Si as the donor element, for example. The concentration of Si included in each of the source region 26 and the drain region 27 is in a range of 1×10¹⁹ cm⁻³ or higher and 5×10²⁰ cm⁻³ or lower.

The gate insulating film 42 is a silicon oxide film (a SiO₂ film), for example. A thickness of the gate insulating film 42 is in a range of 50 nanometers or greater and 100 nanometers or smaller, for example. The gate insulating film 42 is provided on the front surface 10a that can be a flat surface. The gate electrode 44 is provided on the gate insulating film 42. The gate electrode 44 can be a planar-type electrode provided on the flat gate insulating film 42. The gate electrode 44 includes polysilicon doped with impurities, for example.

The source electrode 54 and the drain electrode 56 are each provided on the front surface 10a of the GaN substrate 10. The source electrode 54 is in contact with the source region 26 and the contact region 25. The drain electrode 56 is in contact with the drain region 27. The source electrode 54 and the drain electrode 56 each include Al or an Al—Si alloy, for example. The source electrode 54 and the drain electrode 56 may each be provided with a barrier metal layer interposed between the front surface 10a of the GaN substrate 10 and Al (or the Al—Si alloy). The material used for the barrier metal layer may be titanium (Ti).

FIG. 2 is an enlarged cross-sectional view illustrating the p⁺-type well region 23, an n⁺-type layer 31 (an example of an “n-type region” according to the present disclosure), and a p⁺-type layer 32 (an example of a “p-type region” according to the present disclosure). As illustrated in FIG. 1 and FIG. 2, the lateral MOSFET 1 includes the n⁺-type layer 31 and the p⁺-type layer 32. The p⁺-type layer 32 is located to be opposed to the gate electrode 44 with the gate insulating film 42 interposed. The n⁺-type layer 31 is located to be opposed to the gate electrode 44 with the p⁺-type layer 32 interposed. For example, the n⁺-type layer 31 and the p⁺-type layer 32 are arranged in this order from the well region 23 toward the gate electrode 44.

The n⁺-type layer 31 is interposed between the p⁺-type well region 23 and the p⁺-type layer 32. The n⁺-type layer 31 is in contact with the well region 23 and the p⁺-type layer 32 in the thickness direction (in the Z-axis direction, for example). The n⁺-type layer 31 is also in contact with each of the source region 26 and the drain region 27 in the thickness direction (in the Z-axis direction, for example) or in the direction orthogonal to the thickness direction (in the X-axis direction, for example). FIG. 1 illustrates the case in which the n⁺-type layer 31 is in contact with each of the source region 26 and the drain region 27 in the X-axis direction, namely, in contact with the side surface of the source region 26 and the side surface of the drain region 27.

The n⁺-type layer 31 includes a donor element, such as Si, Ge, and O. The n⁺-type layer 31 is formed such that the donor element such as Si, Ge, and O is implanted into the front surface 10a side of the GaN substrate 10 and is then activated by heat treatment. Alternatively, the n⁺-type layer 31 may be formed by epitaxial growth of an n-type GaN layer containing a donor element.

The p⁺-type layer 32 is a Mg-high-concentration layer heavily doped with Mg as an acceptor element. The Mg concentration in the p⁺-type layer 32 is in a range of 1×10¹⁸ cm⁻³ or higher and 1×10²⁰ cm⁻³ or lower, and preferably in a range of 1×10¹⁹ cm⁻³ or higher and 1×10²⁰ cm⁻³ or lower. The p⁺-type layer 32 may be formed such that impurity ions of Mg are implanted into the front surface 10a side of the GaN substrate 10 and are then activated by heat treatment. Alternatively, the p⁺-type layer 32 may be formed by epitaxial growth of a p-type GaN layer containing Mg.

An effective acceptor concentration in the p⁺-type layer 32 in which the donor concentration is canceled out of the acceptor concentration is defined as Np. The thickness of the p⁺-type layer 32 is defined as dp. An effective donor concentration in the n⁺-type layer 31 in which the acceptor concentration is canceled out of the donor concentration is defined as Nn. The thickness of the n⁺-type layer 31 is defined as dn. The following inequalities (1) and (2) are then fulfilled:

$$[ Math . 2 ]$$

$$3 nm < {d}_{n} ( nm ) < 1.16 \times {10}^{11} \sqrt{\frac{{N}_{p}}{( {N}_{n} + {N}_{p} ) {N}_{n}}} \qquad ( 1 )$$

$$3 nm < {d}_{p} ( nm ) < 5.78 \times {10}^{10} \sqrt{\frac{{N}_{n}}{( {N}_{n} + {N}_{p} ) {N}_{p}}} \qquad ( 2 )$$

When the inequality (2) is fulfilled, the p⁺-type layer 32 is completely depleted in a state in which a bias (a gate bias) toward the gate electrode 44 is zero volts. Leading the gate bias to greater than zero volts can facilitate a change in potential of the n⁺-type layer 31. More particularly, the potential of the n⁺-type layer 31 cannot be changed if the p⁺-type layer 32 is not depleted. The p⁺-type layer 32 is required to be depleted with the gate bias in order to change the potential of the n⁺-type layer 31, which causes an increase in threshold (Vth) of the MOSFET. As described above, the p⁺-type layer 32 is completely depleted with the gate bias of zero volts when the inequality (2) is fulfilled, so as not to need to distribute the gate bias for the complete depletion of the p⁺-type layer 32. This can change the potential of the n⁺-type layer 31 with a lower gate bias, so as to decrease the threshold of the MOSFET to a low level.

In addition, when the inequality (2) and the inequality (1) are both fulfilled, the n⁺-type layer 31 is completely depleted with the gate bias of zero voltages. The complete depletion of the n⁺-type layer 31 with the gate bias set to zero voltages does not cause a drain current to flow through, leading the MOSFET to have normally-off characteristics.

The thickness dn of the n⁺-type layer 31 is set to be greater than three nanometers in the inequality (1). Similarly, the thickness dp of the p⁺-type layer 32 is set to be greater than three nanometers in the inequality (2). This is because of the reasons upon manufacture. Conventional manufacturing technology has a limit to a decrease in layer thickness, since the n⁺-type layer 31 and the p⁺-type layer 32 are presumed to be required to have a thickness of three nanometers or greater in order to keep stability upon the manufacture of the n⁺-type layer 31 and the p⁺-type layer 32. The left term of the respective inequalities (1) and (2) is not required to be three nanometers but may be two nanometers when the decrease in layer thickness to three nanometers or grater will be available due to further development of manufacturing technology.

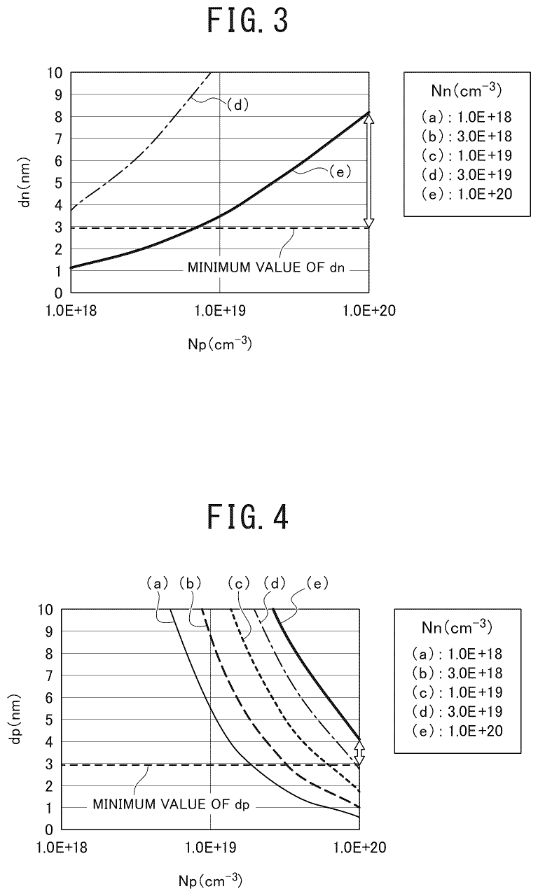

FIG. 3 is a graph showing simulation results obtained by the inventor of the present disclosure, regarding a relation between the effective acceptor concentration Np of the p⁺-type layer 32 and the thickness dn of the n⁺-type layer 31. FIG. 4 is a graph showing simulation results obtained by the inventor of the present disclosure, regarding a relation between the effective acceptor concentration Np of the p⁺-type layer 32 and the thickness dp of the p⁺-type layer 32. As shown in FIG. 3 and FIG. 4, the simulations use the effective acceptor concentration Np of the p⁺-type layer 32 set in the range of 1.0×10¹⁸ cm⁻³ or higher and 1.0×10²⁰ cm⁻³ or lower. The simulations also use the effective donor concentration Nn of the n⁺-type layer 31 set to five cases: 1.0×10¹⁸ cm⁻³, 3.0×10¹⁸ cm⁻³, 1.0×10¹⁹ cm⁻³, 3.0×10¹⁹ cm⁻³, and 1.0×10²⁰ cm⁻³. These set values were applied to the respective inequalities (1) and (2) so as to obtain the results as shown in FIG. 3 and FIG. 4.

FIG. 3 omits the illustration of the results of the three conditions, Nn=1.0×10¹⁸ cm⁻³, 3.0×10¹⁸ cm⁻³, and 1.0×10¹⁹ cm⁻³, because dn results in larger than ten nanometers in the enter range of Np set to 1.0×10¹⁸ cm⁻³ or higher and 1.0×10²⁰ cm⁻³ or lower. The sign “E+” indicated in FIG. 3 and FIG. 4 refers to exponentiation with base 10.

In the present embodiment (Embodiment 1 and Embodiments 2 to 6 described below), when the effective acceptor concentration Np of the p⁺-type layer 32, which is the effective Mg concentration in which the donor element is canceled out of the Mg concentration, for example, is in the range of 1.0×10¹⁸ cm⁻³ or higher and 1.0×10²⁰ cm⁻³ or lower, the thickness dn of the n⁺-type layer 31 is greater than three nanometers, and is in a range of smaller values than the respective curves for each Nn, as shown in FIG. 3. Similarly, the thickness dp of the p⁺-type layer 32 is greater than three nanometers, and is in a range of smaller values than the respective curves for each Nn.

A presumption example according to the present embodiment is illustrated below with a case of Np=1.0×10²⁰ cm⁻³ and Nn=1.0×10²⁰ cm⁻³. In this presumption, the inequalities (1) and (2) are fulfilled when the thickness dn of the n⁺-type layer 31 is greater than three nanometers and less than eight nanometers, as indicated by the double ended arrow in FIG. 3. Similarly, in this presumption, the inequalities (1) and (2) are fulfilled when the thickness dp of the p⁺-type layer 32 is greater than three nanometers and less than four nanometers, as indicated by the double ended arrow in FIG. 4. Namely, the present embodiment is applied to the case of 3 nm<dn<8 nm and 3 nm<dp<4 nm when Np=1.0×10²⁰ cm⁻³ and Nn=1.0×10²⁰ cm⁻³.

As another example, the present embodiment is applied to a case of 3 nm<dn<88 nm and 3 nm<dp<7 nm when Np=1.0×10¹⁹ cm⁻³ and Nn=1.5×10¹⁸ cm⁻³. The present embodiment is also applied to a case of 3 nm<dn<42 nm and 3 nm<dp<11 nm when Np=1.0×10¹⁹ cm⁻³ and Nn=5.0×10¹⁸ cm⁻³. The present embodiment is also applied to a case of 3 nm<dn<19 nm and 3 nm<dp<14 nm when Np=1.0×10¹⁹ cm⁻³ and Nn=1.5×10¹⁹ cm⁻³.

In the present embodiment (Embodiment 1 and Embodiments 2 to 6 described below), the following inequation (3) is preferably fulfilled, in addition to the inequations (1) and (2) described above:

$$dp \times Np - dn \times Nn < 1 \times 1 {0}^{18} \times [ dp + dn ] \qquad ( 3 )$$

This can decrease an effective surface concentration of each of the n⁺-type layer 31 and the p⁺-type layer 32 to a predetermined level or lower, namely, decrease an average acceptor concentration to 1×10¹⁸ cm⁻³ or lower, so as to lead the threshold of the MOSFET to be within a predetermined voltage range.

### (Effects of Embodiment 1)

As described above, the nitride semiconductor device according to Embodiment 1 of the present disclosure includes the GaN substrate 10, and the lateral MOSFET 1 having the normally-off characteristics provided in the GaN substrate 10. The lateral MOSFET 1 includes the gate insulating film 42 provided on the front surface 10a side of the GaN substrate 10, the gate electrode 44 provided on the gate insulating film 42, the p⁺-type layer 32 opposed to the gate electrode 44 with the gate insulating film 42 interposed, and the n⁺-type layer 31 opposed to the gate electrode 44 with the p⁺-type layer 32 interposed so as to be in contact with the p⁺-type layer 32. The Mg concentration in the p⁺-type layer 32 is set in the range of 1×10¹⁸ cm⁻³ or higher and 1×10²⁰ cm⁻³ or lower. The respective inequalities (1) and (2) described above are fulfilled, where the effective acceptor concentration of the p⁺-type layer 32 is Np (cm⁻³), the thickness of the p⁺-type layer 32 is dp (nm), the effective donor concentration of the n⁺-type layer 31 is Nn (cm⁻³), and the thickness of the n⁺-type layer 31 is dn (nm).

This configuration leads the n⁺-type layer 31 to serve as a channel in the lateral MOSFET 1. The n⁺-type layer 31 is completely depleted in the state in which the bias (the gate bias) toward the gate electrode 44 is zero volts, so as to exhibit the normally-off characteristics. This can introduce Mg into the interface between the GaN substrate 10 and the gate insulating film 42 at a high concentration while decreasing the threshold of the lateral MOSFET 1 to a low level, so as to inactivate a hole-trapping state caused at the interface.

### (Modified Example)

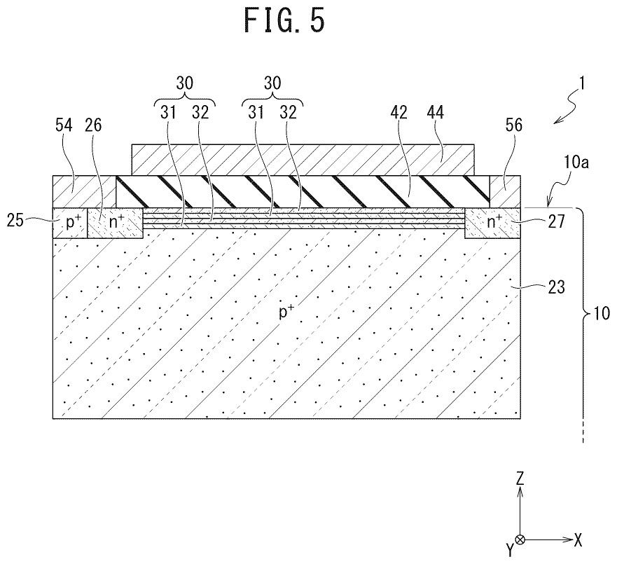

FIG. 5 is a cross-sectional view illustrating a modified example of the lateral MOSFET 1 according to Embodiment 1 of the present disclosure. As illustrated in FIG. 5, the lateral MOSFET 1 may include plural n⁺-type layers 31 and plural p⁺-type layers 32. For example, in a case in which a set of the n⁺-type layer 31 and the p⁺-type layer 32 is defined as a pair 30, the n-number of the pairs 30 (n is an integer of two or greater) may be arranged to overlap with each other at a position opposed to the gate electrode 44 with the gate insulating film 42 interposed. Namely, the n⁺-type layer 31 and the p⁺-type layer 32 may be alternatively and repeatedly arranged in this order from the well region 23 toward the gate electrode 44. FIG. 5 illustrates the case of including two pairs 30 (n=2) of the n⁺-type layer 31 and the p⁺-type layer 32.

The inequalities (1) and (2) described above are also fulfilled in the modified example illustrated in FIG. 5. The plural pairs 30 each have a configuration in which the Mg concentration in the p⁺-type layer 32 is set in the range of 1×10¹⁸ cm⁻³ or higher and 1×10²⁰ cm⁻³ or lower. In each pair 30, the effective acceptor concentration of the p⁺-type layer 32 is defined as Np, the thickness of the p⁺-type layer 32 is defined as dp (nm), the effective donor concentration of the n⁺-type layer 31 is defined as Nn, and the thickness of n⁺-type layer 31 is defined as dn. The thickness dn of the n⁺-type layer 31 and the thickness dp of the p⁺-type layer 32 fulfill the inequalities (1) and (2) described above. The modified example illustrated in FIG. 5 thus can achieve the effects similar to those in Embodiment 1.

### Embodiment 2

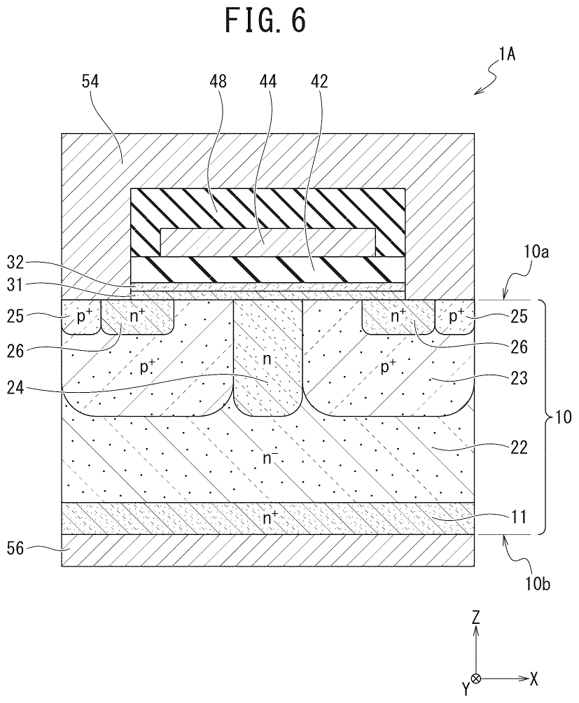

Embodiment 1 is illustrated above with the lateral MOSFET as an example of the “transistor” according to the present disclosure. The “transistor” according to the present disclosure is not limited to the lateral type, and can be a vertical type instead. FIG. 6 is a cross-sectional view illustrating a configuration example of a vertical MOSFET 1A having normally-off characteristics according to Embodiment 2 of the present disclosure. As illustrated in FIG. 6, the vertical MOSFET 1A is provided in the GaN substrate 10.

The GaN substrate 10 includes a GaN single-crystal substrate 11 of n⁺-type, and a GaN layer 22 of n-type provided on the GaN single-crystal substrate 11, for example. As illustrated in FIG. 6, the GaN substrate 10 has a rear surface 10b on the opposite side of the front surface 10a. The rear surface 10b conforms to a rear surface of the GaN single-crystal substrate 11. An n-type dopant element included in the GaN single-crystal substrate 11 is at least one of silicon (Si), oxygen (O), and germanium (Ge), and can be O, for example. An impurity concentration of O included in the GaN single-crystal substrate 11 is 2×10¹⁸/cm³ or higher.

The GaN single-crystal substrate 11 may be a low-dislocation free-standing GaN substrate having a threading dislocation density of less than 1×10⁷ cm⁻², for example. Since the GaN single-crystal substrate 11 is a low-dislocation free-standing GaN substrate, the GaN layer 22 to be formed on the GaN single-crystal substrate 11 also has a low dislocation density. The use of the low-dislocation free-standing GaN substrate as the GaN single-crystal substrate 11 can minimize a current leakage from a power device having a large area regardless of whether to be formed in the GaN single-crystal substrate 11. A manufacturing apparatus thus can enable high-yield-rate manufacture of power devices. In addition, this case can avoid a deep diffusion of the implanted impurity ions along the dislocation during heat treatment.

The GaN layer 22 is provided on the GaN single-crystal substrate 11. The GaN layer 22 is an n-type GaN single-crystal layer epitaxially grown on the GaN single-crystal substrate 11. An n-type dopant element (n-type impurities) included in the GaN layer 22 is at least one of silicon (Si), oxygen (O), and germanium (Ge), and can be O, for example. The front surface 10a of the GaN substrate 10, which is also the front surface of the GaN layer 22, may be a c-plane (a Ga plane) that is a polar surface, or may be an m-plane that is a non-polar surface.

As illustrated in FIG. 6, the vertical MOSFET 1A includes the gate insulating film 42 provided on the front surface 10a side of the GaN substrate 10, the gate electrode 44 provided on the gate insulating film 42, the p⁺-type well region 23 provided in the GaN layer 22, the n⁺-type source region 26 provided adjacent to the front surface of the well region 23 under both sides of the gate electrode 44, the p⁺-type contact region 25 provided adjacent to the front surface 10a of the GaN substrate 10 so as to be in contact with the well region 23, the source electrode 54 provided on the front surface 10a side of the GaN substrate 10 so as to be in contact with the source region 26 and the contact region 25, an interlayer insulating film 48 provided for insulating the source electrode 54 from the gate electrode 44, and the drain electrode 56 provided on the rear surface 10b side of the GaN substrate 10.

The vertical MOSFET 1A further includes a JFET region 24 of n-type provided in the GaN layer 22. The JFET region 24 is located at a position opposed to the gate electrode 44 with the gate insulating film 42 interposed. The JFET region 24 faces the front surface 10a of the GaN substrate 10, and is in contact with the n⁺-type layer 31 in the thickness direction of the vertical MOSFET 1A (in the Z-axis direction, for example). The JFET region 24 is also in contact with the well region 23 in the direction orthogonal to the thickness direction of the vertical MOSFET 1A (in the X-axis direction, for example). While FIG. 6 illustrates the case in which the depth of the JFET region 24 from the front surface 10a is the same as the depth of the well region 23 from the front surface 10a, the JFET region 24 may have a greater depth from the front surface 10a than the well region 23.

A region in the GaN layer 22 not provided with any of the well region 23, the source region 26, or the contact region 25 can be referred to as a drift region. The JFET region 24 is also a part of the drift region. The drift region serves as a current path between the GaN single-crystal substrate 11 and the well region 23.

As illustrated in FIG. 6, the vertical MOSFET 1A includes the n⁺-type layer 31 and the p⁺-type layer 32 between the front surface 10a of the GaN substrate 10 and the gate insulating film 42. As in the case of the lateral MOSFET 1 illustrated in FIG. 1, the vertical MOSFET 1A illustrated in FIG. 6 includes the p⁺-type layer 32 located at the position opposed to the gate electrode 44 with the gate insulating film 42 interposed. The n⁺-type layer 31 located at the position opposed to the gate electrode 44 with the p⁺-type layer 32 interposed. The n⁺-type layer 31 and the p⁺-type layer 32 are arranged in this order from the well region 23 toward the gate electrode 44, for example.

The n⁺-type layer 31 is interposed between the p⁺-type well region 23 and the p⁺-type layer 32. The n⁺-type layer 31 is in contact with each of the well region 23 and the p⁺-type layer 32 in the thickness direction (in the Z-axis direction, for example). The n⁺-type layer 31 is also in contact with the source region 26 in the thickness direction (in the Z-axis direction, for example) or in the direction orthogonal to the thickness direction (in the X-axis direction, for example). FIG. 6 illustrates the case in which the n⁺-type layer 31 is in contact with the source region 26 in the Z-axis direction, namely, in contact with the top surface of the source region 26.

As in the case of the lateral MOSFET 1 illustrated in FIG. 1, the vertical MOSFET 1A illustrated in FIG. 6 (and vertical MOSFETs 1B and 1C described below) has the configuration in which the n⁺-type layer 31 includes a donor element (Si, Ge, or O, for example). The n⁺-type layer 31 is formed such that the donor element (Si, Ge, or O, for example) is implanted into the front surface 10a side of the GaN substrate 10 and is then activated by heat treatment. Alternatively, the n⁺-type layer 31 may be formed by epitaxial growth of an n-type GaN layer containing the donor element.

In addition, the vertical MOSFET 1A illustrated in FIG. 6 (and vertical MOSFETs 1B and 1C described below) also has the configuration in which the p⁺-type layer 32 is the Mg-high-concentration layer heavily doped with Mg as an acceptor element. The Mg concentration in the p⁺-type layer 32 is in a range of 1×10¹⁸ cm⁻³ or higher and 1×10²⁰ cm⁻³ or lower, and preferably in a range of 1×10¹⁹ cm⁻³ or higher and 1×10²⁰ cm⁻³ or lower. The p⁺-type layer 32 may be formed such that the acceptor element of Mg is implanted into the front surface 10a side of the GaN substrate 10 and are then activated by heat treatment. Alternatively, the p⁺-type layer 32 may be formed by epitaxial growth of a p-type GaN layer including Mg.

Further, the vertical MOSFET 1A illustrated in FIG. 6 also has the configuration in which the thickness dn of the n⁺-type layer 31 and the thickness dp of the p⁺-type layer 32 fulfil the inequalities (1) and (2) described above, where the effective acceptor concentration of the p⁺-type layer 32 is Np and the effective donor concentration of the n⁺-type layer 31 is Nn. The examples for the respective values of Np, dp, Nn, and dn in the lateral MOSFET 1 described with reference to FIG. 3 and FIG. 4 are also applied to the vertical MOSFET 1A illustrated in FIG. 6 (and vertical MOSFETs 1B and 1C described below). For example, the present embodiment is applied to the case of 3 nm<dn<8 nm and 3 nm<dp<4 nm when Np=1.0×10²⁰ cm⁻³ and Nn=1.0×10²⁰ cm⁻³. The same is also applied to the numerical ranges regarding Np, dp, Nn, and dn illustrated as the “other example”.

The nitride semiconductor device according to the present disclosure may have a configuration in which the vertical MOSFET 1A illustrated in FIG. 6, when defined as a single unit structure, is repeatedly arranged in one direction (in the X-axis direction, for example) so as to have plural unit structures. The same is also applied to Embodiments 3 to 6 described below. The vertical MOSFET 1B or 1C, when defined as a single unit structure, can be repeatedly arranged in one direction so as to have plural unit structures.

### (Effects of Embodiment 2)

As described above, the nitride semiconductor device according to Embodiment 2 of the present disclosure includes the GaN substrate 10, and the vertical MOSFET 1A having the normally-off characteristics provided in the GaN substrate 10. The vertical MOSFET 1A includes the gate insulating film 42 provided on the front surface 10a side of the GaN substrate 10, the gate electrode 44 provided on the gate insulating film 42, the p⁺-type layer 32 opposed to the gate electrode 44 with the gate insulating film 42 interposed, and the n⁺-type layer 31 opposed to the gate electrode 44 with the p⁺-type layer 32 interposed so as to be in contact with the p⁺-type layer 32. The Mg concentration in the p⁺-type layer 32 is set in the range of 1×10¹⁸ cm⁻³ or higher and 1×10²⁰ cm⁻³ or lower. The respective inequalities (1) and (2) described above are fulfilled, where the effective acceptor concentration of the p⁺-type layer 32 is Np (cm⁻³), the thickness of the p⁺-type layer 32 is dp (nm), the effective donor concentration of the n⁺-type layer 31 is Nn (cm⁻³), and the thickness of the n⁺-type layer 31 is dn (nm).

This configuration leads the n⁺-type layer 31 to serve as a channel in the vertical MOSFET 1A. The n⁺-type layer 31 is completely depleted in the state in which the gate bias is zero volts, so as to exhibit the normally-off characteristics. This can introduce Mg into the interface between the GaN substrate 10 and the gate insulating film 42 at a high concentration while decreasing the threshold of the vertical MOSFET 1A to a low level, so as to inactivate a hole-trapping state caused at the interface.

### (Modified Examples)

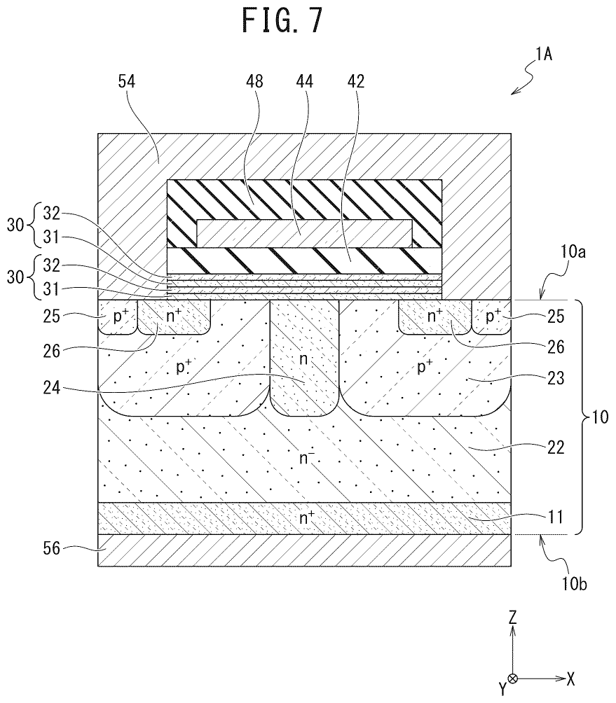

(I) FIG. 7 is a cross-sectional view illustrating a modified example of the vertical MOSFET 1A according to Embodiment 2 of the present disclosure. As illustrated in FIG. 7, the vertical MOSFET 1A may include plural n⁺-type layers 31 and plural p⁺-type layers 32. In a case in which a set of the n⁺-type layer 31 and the p⁺-type layer 32 is defined as a pair 30, the n-number of the pairs 30 (n is an integer of two or greater) may be arranged to overlap with each other at a position opposed to the gate electrode 44 with the gate insulating film 42 interposed. Namely, the n⁺-type layer 31 and the p⁺-type layer 32 may be alternatively and repeatedly arranged in this order from the well region 23 toward the gate electrode 44. FIG. 7 illustrates the case of including two pairs 30 (n=2) of the n⁺-type layer 31 and the p⁺-type layer 32.

The inequalities (1) and (2) described above are also fulfilled in the modified example illustrated in FIG. 7. The respective pairs 30 have a configuration in which the Mg concentration in the p⁺-type layer 32 is set in the range of 1×10¹⁸ cm⁻³ or higher and 1×10²⁰ cm⁻³ or lower. In each pair 30, the thickness dn of the n⁺-type layer 31 and the thickness dp of the p⁺-type layer 32 fulfill the inequalities (1) and (2) described above, where the effective acceptor concentration of the p⁺-type layer 32 is Np, and the effective donor concentration of the n⁺-type layer 31 is Nn. The modified example illustrated in FIG. 7 thus can achieve the same effects as Embodiment 2 described above.

(II) FIG. 6 and FIG. 7 each illustrate the case of arranging the n⁺-type layer 31 and the p⁺-type layer 32 on the JFET region 24. The present embodiment, however, does not need to provide the n⁺-type layer 31 or the p⁺-type layer 32 on the JFET region 24. In particular, the n⁺-type layer 31 and the p⁺-type layer 32 may be only arranged on the well region 23 but not arranged on the JFET region 24. In such a case, an n-type region may be provided so as to connect the n⁺-type layer 31 and the JFET region 24 together. This configuration can also achieve the same effects as Embodiment 2 described above.

(III) FIG. 6 and FIG. 7 each illustrate the case in which the vertical MOSFET 1A include the JFET region 24. The JFET region 24, however, is not required to be provided in the present embodiment. The n-type GaN layer 22 may be provided, instead of the JFET region, between the well region on one side and the well region on the other side arranged adjacent to each other in the X-axis direction in FIG. 6 and FIG. 7. This configuration increases an ON-resistance, but can achieve the same effects as Embodiment 2 described above.

(IV) FIG. 6 and FIG. 7 each illustrate the case of arranging the n⁺-type layer 31 and the p⁺-type layer 32 on the front surface 10a of the GaN substrate 10. The present embodiment, however, does not need to arrange the n⁺-type layer 31 or the p⁺-type layer 32 on the front surface 10a of the GaN substrate 10 but may include the n⁺-type layer 31 and the p⁺-type layer 32 inside the GaN substrate 10, as in the case of the lateral MOSFET 1 illustrated in FIG. 1. In such a case, the n⁺-type layer 31 may be in contact with the side surfaces of the source region 26. This configuration can also achieve the same effects as Embodiment 2 described above.

(V) The p⁺-type contact region 25 may have the same acceptor concentration (or the effective acceptor concentration) as the p⁺-type well region 23. In such a case, the p⁺-type contact region 25 may be provided as a part of the p⁺-type well region 23. In particular, in FIG. 6 and FIG. 7, the source electrode 54 may be in contact with a part of the p⁺-type well region 23 implemented by the p⁺-type contact region 25. This configuration can also achieve the same effects as Embodiment 2 described above.

### Embodiment 3

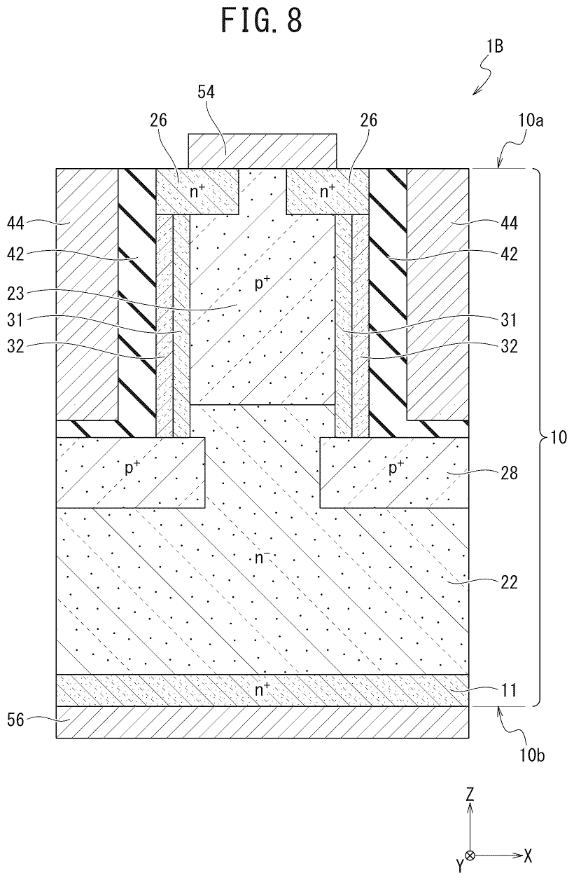

Embodiment 2 is illustrated above with the planar-gate vertical MOSFET as an example of the “transistor” according to the present disclosure. The vertical MOSFET according to the embodiment of the present disclosure is not limited to the planar-gate type, and may be a trench-gate type. FIG. 8 is a cross-sectional view illustrating a configuration example of a vertical MOSFET 1B having normally-off characteristics according to Embodiment 3 of the present disclosure. As illustrated in FIG. 8, the vertical MOSFET 1B is the trench-gate type, which has trenches provided on the front surface 10a side of the GaN substrate 10. The gate insulating film 42 is provided on the respective side and bottom surfaces of the trenches. The gate electrode 44 is arranged inside the trenches with the gate insulating film 42 interposed. The respective side surfaces of the trenches may be either a c-plane or an m-plane.

The vertical MOSFET 1B further includes a p⁺-type region 28 provided in the GaN substrate 10. The p⁺-type region 28 is located at the bottom of the respective trenches. A depletion layer provided between the p⁺-type region 28 and the n-type GaN layer 22 can enhance breakdown voltage during a gate-off state.

As illustrated in FIG. 8, the vertical MOSFET 1B includes the n⁺-type layer 31 and the p⁺-type layer 32 between the GaN substrate 10 and the gate insulating film 42. The p⁺-type layer 32 is located at a position opposed to the gate electrode 44 with the gate insulating film 42 interposed along the side surfaces of the trenches. The n⁺-type layer 31 is located at a position opposed to the gate electrode 44 with the p⁺-type layer 32 interposed. The n⁺-type layer 31 and the p⁺-type layer 32 are arranged in this order from the well region 23 toward the gate electrode 44 (from the well region 23 toward the trenches), for example.

The n⁺-type layer 31 is interposed between the p⁺-type well region 23 and the p⁺-type layer 32. The n⁺-type layer 31 is in contact with each of the well region 23 and the p⁺-type layer 32 in the thickness direction (in the X-axis direction in this example). The n⁺-type layer 31 is also in contact with the source region 26 at one end and the p⁺-type layer 28 at the other end in the direction (the Z-axis direction in this example) orthogonal to the thickness direction (the X-axis direction in this example).

### (Effects of Embodiment 3)

As in the case of the lateral MOSFET 1 or the vertical MOSFET 1A described above, the vertical MOSFET 1B illustrated in FIG. 8 has the configuration in which the respective inequalities (1) and (2) described above are fulfilled, where the effective acceptor concentration of the p⁺-type layer 32 is Np (cm⁻³), the thickness of the p⁺-type layer 32 is dp (nm), the effective donor concentration of the n⁺-type layer 31 is Nn (cm⁻³), and the thickness of the n⁺-type layer 31 is dn (nm). This configuration leads the n⁺-type layer 31 to serve as a channel in the vertical MOSFET 1B. The n⁺-type layer 31 is completely depleted in the state in which the gate bias is zero volts, so as to exhibit the normally-off characteristics. This can introduce Mg into the interface between the GaN substrate 10 and the gate insulating film 42 at a high concentration while decreasing the threshold of the vertical MOSFET 1B to a low level, so as to inactivate a hole-trapping state caused at the interface.

### (Modified Example)

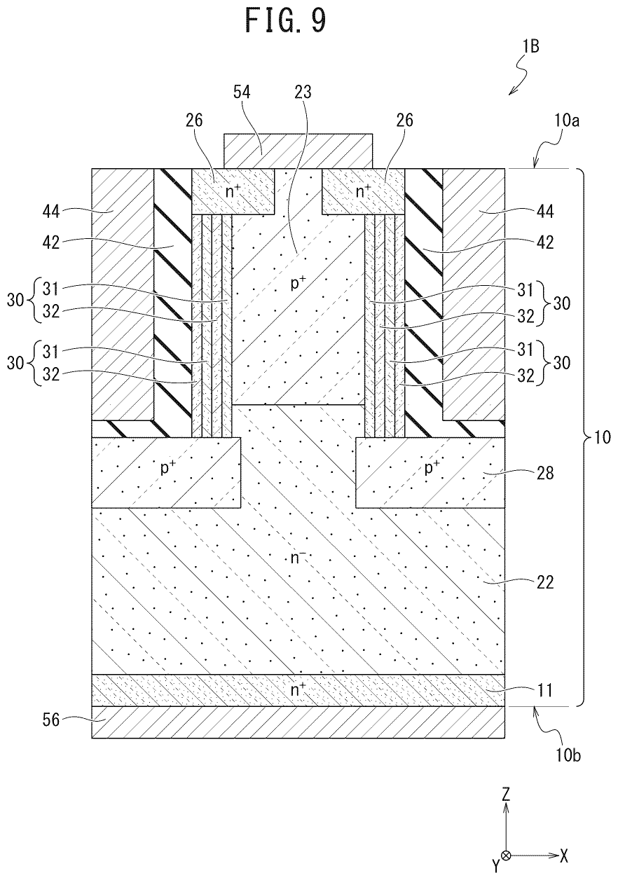

(I) FIG. 9 is a cross-sectional view illustrating a modified example of the vertical MOSFET 1B according to Embodiment 3 of the present disclosure. As illustrated in FIG. 9, the vertical MOSFET 1B may include plural n⁺-type layers 31 and plural p⁺-type layers 32. In a case in which a set of the n⁺-type layer 31 and the p⁺-type layer 32 is defined as a pair 30, the n-number of the pairs 30 (n is an integer of two or greater) may be arranged to overlap with each other at a position opposed to the gate electrode 44 with the gate insulating film 42 interposed. Namely, the n⁺-type layer 31 and the p⁺-type layer 32 may be alternatively and repeatedly arranged in this order from the well region 23 toward the gate electrode 44. FIG. 9 illustrates the case of including two pairs 30 (n=2) of the n⁺-type layer 31 and the p⁺-type layer 32.

The inequalities (1) and (2) described above are also fulfilled in the modified example illustrated in FIG. 9. The respective pairs 30 have the configuration in which the Mg concentration in the p⁺-type layer 32 is set in the range of 1×10¹⁸ cm⁻³ or higher and 1×10²⁰ cm⁻³ or lower. In each pair 30, the thickness dn of the n⁺-type layer 31 and the thickness dp of the p⁺-type layer 32 fulfill the inequalities (1) and (2) described above, where the effective acceptor concentration of the p⁺-type layer 32 is Np, and the effective donor concentration of the n⁺-type layer 31 is Nn. The modified example illustrated in FIG. 9 thus can achieve the same effects as Embodiment 3 described above.

### Embodiment 4

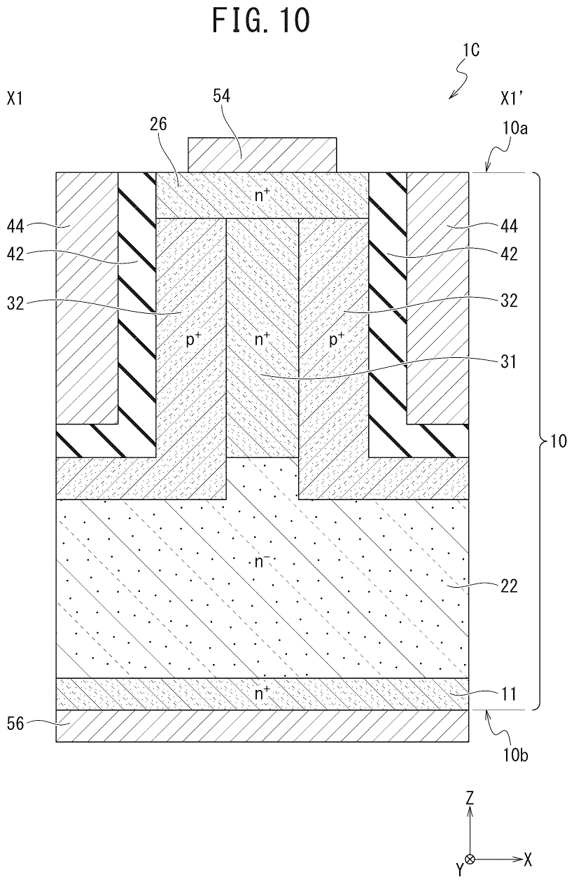

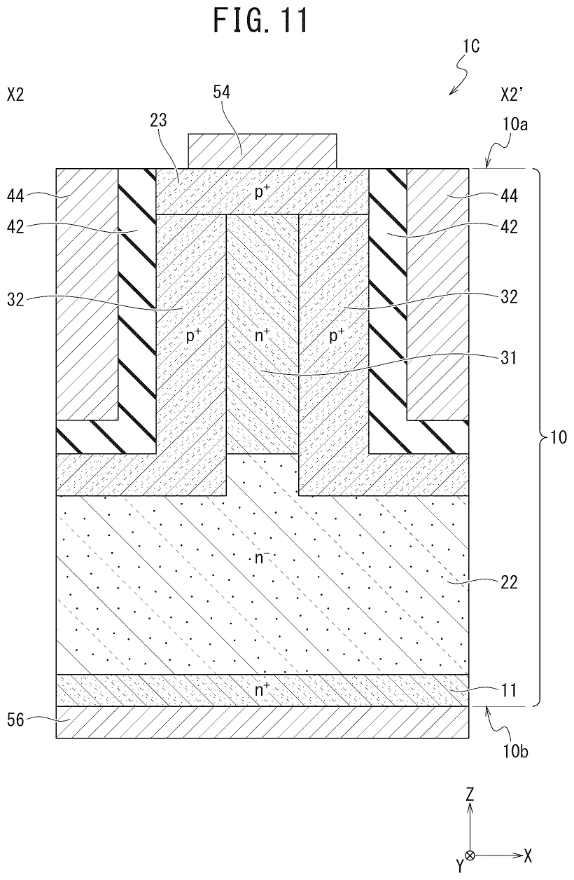

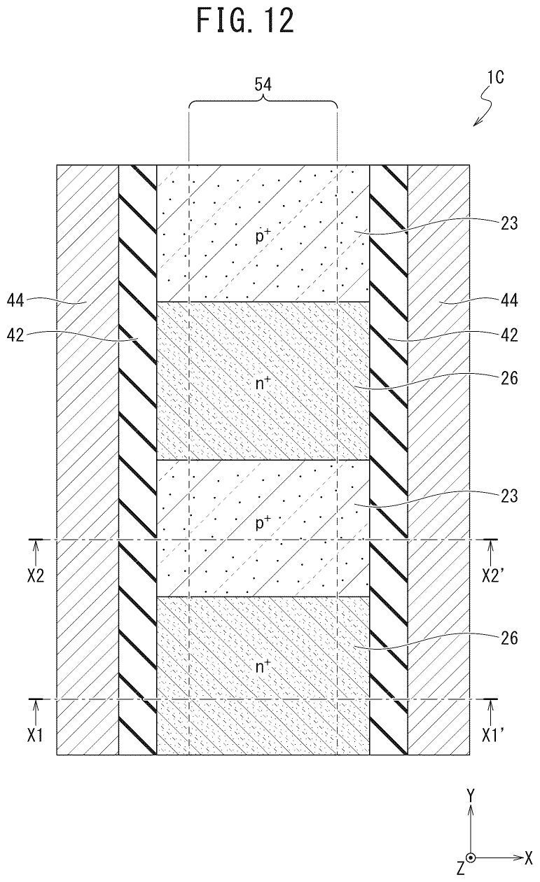

The vertical MOSFET according to the embodiment of the present disclosure may be a FinFET. A FinFET has a configuration in which a distance between a gate electrode on one side and a gate electrode on the other side adjacent to each other in one direction (in the X-axis direction, for example) is shorter than that in a trench-gate type. FIG. 10 to FIG. 12 are cross-sectional and plan views each illustrating a configuration example of a vertical MOSFET 1C having normally-off characteristics according to Embodiment 4 of the present disclosure. FIG. 10 is the cross-sectional view taken along line X1-X1′ in the plan view of FIG. 12. FIG. 11 is the cross-sectional view taken along line X2-X2′ in the plan view of FIG. 12. FIG. 12 indicates the source electrode 54 by the broken line for clearly defining the boundary between the n⁺-type source region 26 and the p⁺-type contact region.

The vertical MOSFET 1C illustrated in FIG. 10 to FIG. 12 is the FinFET, which has trenches provided on the front surface 10a side of the GaN substrate 10. The gate insulating film 42 is provided on the respective side and bottom surfaces of the trenches. The gate electrode 44 is arranged inside the trenches with the gate insulating film 42 interposed. The respective side surfaces of the trenches may be either a c-plane or an m-plane.

The vertical MOSFET 1C also has a Fin part. The Fin part is a member located on the front surface 10a side of the GaN substrate 10 and interposed between one trench and the other trench adjacent to each other in one direction (in the X-axis direction, for example). The Fin part is provided with the n⁺-type layer 31 and the p⁺-type layer 32. For example, as illustrated in FIG. 10 and FIG. 11, the Fin part is provided with the n⁺-type layer 31 and the p⁺-type layer 32 located on both sides of the n⁺-type layer 31.

The vertical MOSFET 1C also has the configuration in which the p⁺-type layer 32 is located at the position opposed to the gate electrode 44 with the gate insulating film 42 interposed along the side surfaces of the trenches. The n⁺-type layer 31 is located at the position opposed to the gate electrode 44 with the p⁺-type layer 32 interposed. The both sides of the n⁺-type layer 31 are in contact with the p⁺-type layer 32 in the thickness direction (in the X-axis direction in this example). The n⁺-type layer 31 is also in contact with the n⁺-type source region 26 or the p⁺-type well region 23 at one end and is in contact with the n-type GaN layer 22 (the drift region) at the other end in the direction (the Z-axis direction in this example) orthogonal to the thickness direction (the X-axis direction in this example).

### (Effects of Embodiment 4)

As in the case of the lateral MOSFET 1 or the vertical MOSFET 1A or 1B described above, the vertical MOSFET 1C illustrated in FIG. 10 to FIG. 12 has the configuration in which the respective inequalities (1) and (2) described above are fulfilled, where the effective acceptor concentration of the p⁺-type layer 32 is Np (cm⁻³), the thickness of the p⁺-type layer 32 is as dp (nm), the effective donor concentration of the n⁺-type layer 31 is Nn (cm⁻³), and the thickness of the n⁺-type layer 31 is dn (nm). This configuration leads the n⁺-type layer 31 to serve as a channel in the vertical MOSFET 1C. The n⁺-type layer 31 is completely depleted in the state in which the gate bias is zero volts, so as to exhibit the normally-off characteristics. This can introduce Mg into the interface between the GaN substrate 10 and the gate insulating film 42 at a high concentration while decreasing the threshold of the vertical MOSFET 1C to a low level, so as to inactivate a hole-trapping state caused at the interface.

### (Modified Example)

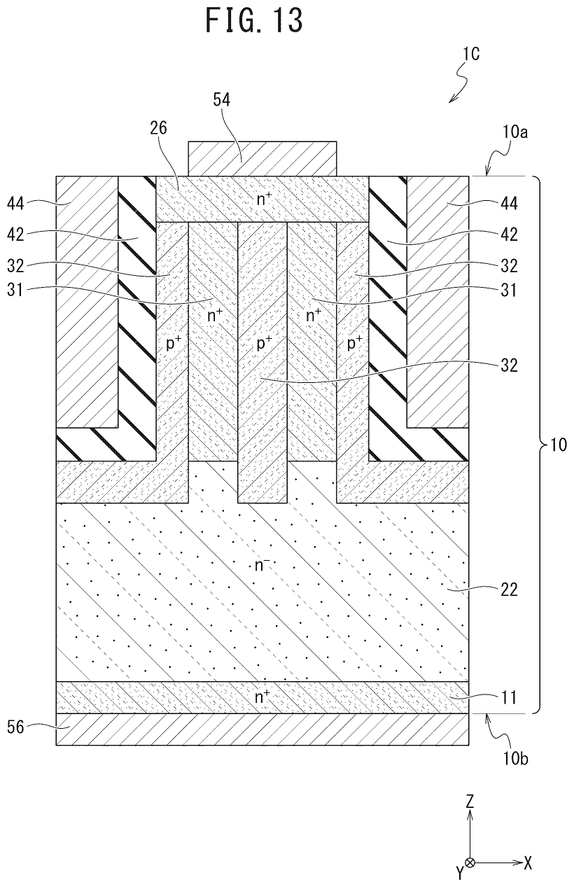

FIG. 13 is a cross-sectional view illustrating a modified example of the vertical MOSFET 1C according to Embodiment 4 of the present disclosure. As illustrated in FIG. 13, the vertical MOSFET 1C may include plural n⁺-type layers 31 and plural p⁺-type layers 32. In a case in which a set of the n⁺-type layer 31 and the p⁺-type layer 32 is defined as a pair 30, the n-number of the pairs 30 (n is an integer of two or greater) may be arranged to overlap with each other. FIG. 13 illustrates a case of including two pairs 30 (n=2) of the n⁺-type layer 31 and the p⁺-type layer 32 and further including another p⁺-type layer 32 in the single Fin part. The other p⁺-type layer 32 may be the p⁺-type layer 32 in contact with the gate insulating film 42 in the arrow direction of the X-axis, or may be the p⁺-type layer 32 in contact with the gate insulating film 42 in the direction opposite to the arrow direction of the X-axis.

The inequalities (1) and (2) described above are also fulfilled in the modified example of the vertical MOSFET 1C illustrated in FIG. 13. The respective pairs 30 have the configuration in which the Mg concentration in the p⁺-type layer 32 is set in the range of 1×10¹⁸ cm⁻³ or higher and 1×10²⁰ cm⁻³ or lower. In each pair 30, the thickness dn of the n⁺-type layer 31 and the thickness dp of the p⁺-type layer 32 fulfill the inequalities (1) and (2) described above, where the effective acceptor concentration of the p⁺-type layer 32 is Np, and the effective donor concentration of the n⁺-type layer 31 is Nn. The modified example illustrated in FIG. 13 thus can achieve the same effects as Embodiment 4 described above.

### Embodiment 5

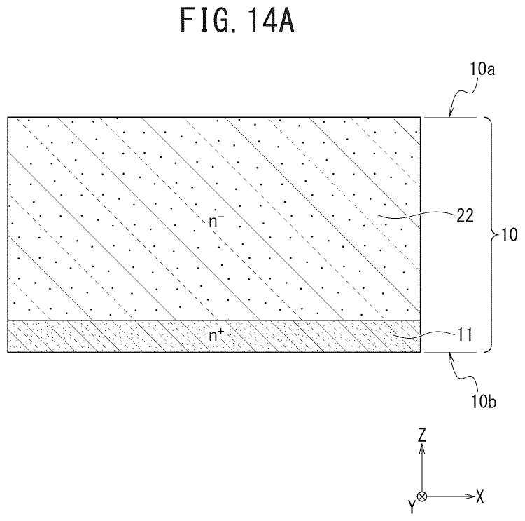

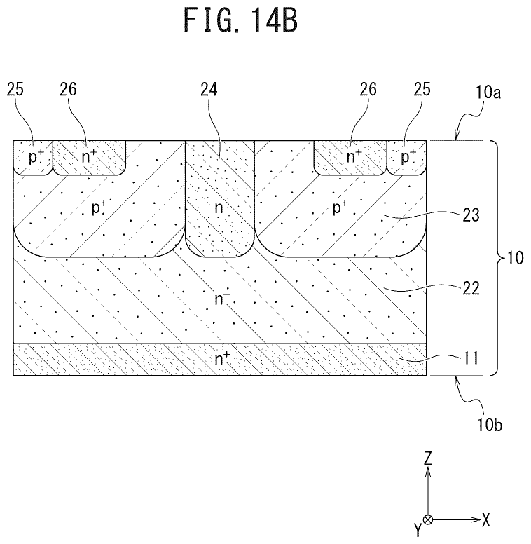

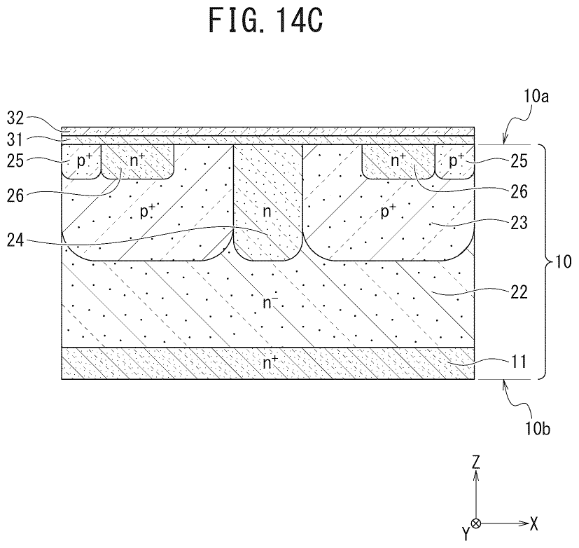

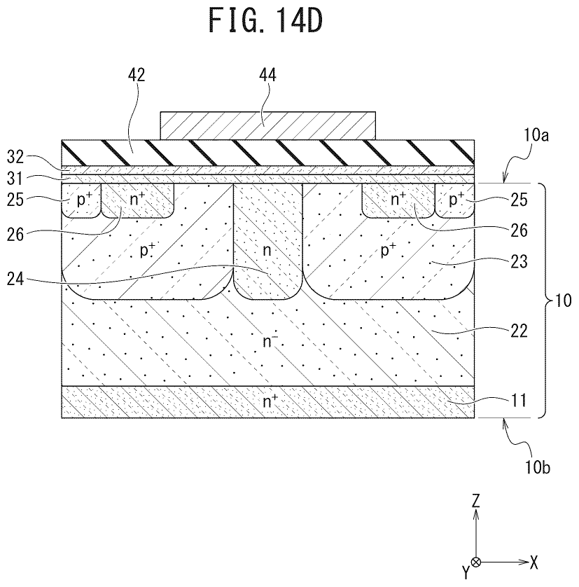

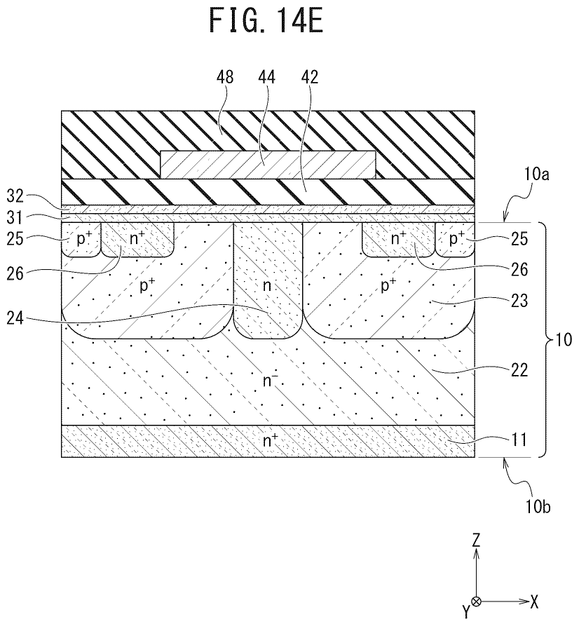

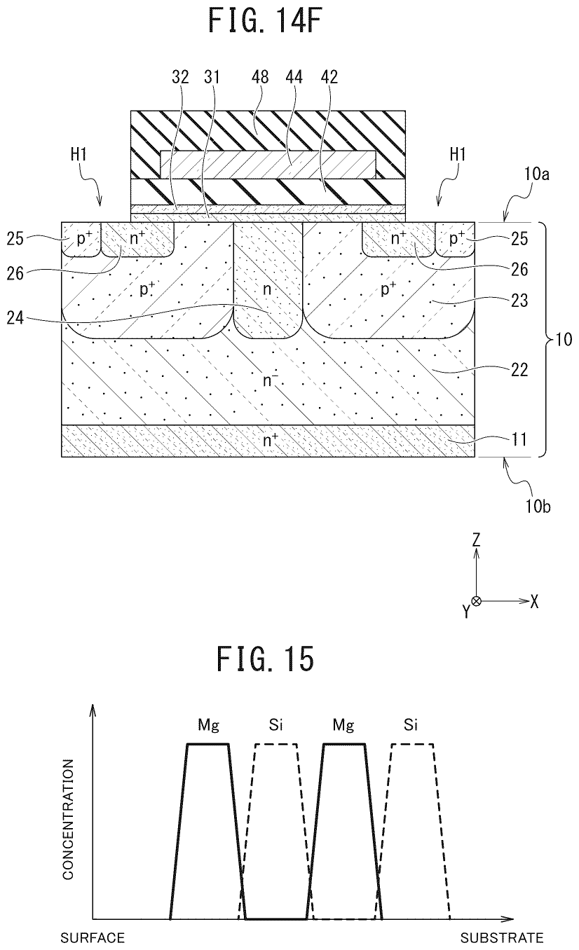

A method of manufacturing a planar-type vertical MOSFET (a vertical DMOS) according to Embodiment 5 of the present disclosure is described below. FIG. 14A to FIG. 14F are cross-sectional views illustrating a sequential process of the method of manufacturing the vertical MOSFET according to Embodiment 5 of the present disclosure. The vertical MOSFET is manufactured by use of various kinds of apparatuses, such as a film-forming apparatus, an exposing apparatus, an ion implantation apparatus, an etching apparatus, and a heat treatment apparatus. These apparatuses are collectively referred to below as a manufacturing apparatus.

As illustrated in FIG. 14A, the manufacturing apparatus epitaxially grows the n-type GaN layer 22 on the n⁺-type GaN single-crystal substrate 11. Next, as illustrated in FIG. 14B, the manufacturing apparatus sequentially implants an acceptor element (such as Mg) and a donor element (such as O and Si) into the GaN layer 22 by photolithography and ion implantation, and then executes heat treatment so as to form the p⁺-type well region 23, the n-type JFET region 24, the p⁺-type contact region 25, and the n⁺-type source region 26. While this embodiment is illustrated with the case of forming the p⁺-type contact region 25, the formation of the contact region 25 may be omitted. In such a case, the p⁺-type well region 23 is elongated toward the position corresponding to the contact region 25 to be formed.

Next, as illustrated in FIG. 14C, the manufacturing apparatus epitaxially grows the n⁺-type layer 31 and the p⁺-type layer 32 in this order on the front surface 10a of the GaN substrate 10. The n⁺-type layer 31 and the p⁺-type layer 32 in this case are sequentially epitaxially grown so that the Mg concentration in the p⁺-type layer 32 is in a range of 1×10¹⁸ cm⁻³ or higher and 1×10²⁰ cm⁻³ or lower, preferably in a range of 1×10¹⁹ cm⁻³ or higher and 1×10²⁰ cm⁻³ or lower, and the effective donor concentration Nn (cm⁻³) and the thickness dn (nm) of the n⁺-type layer 31 and the effective acceptor concentration Np (cm⁻³) and the thickness Nn (nm) of the p⁺-type layer 32 fulfill the respective inequalities (1) and (2) described above.

Next, as illustrated in FIG. 14D, the manufacturing apparatus sequentially forms the gate insulating film 42 and the gate electrode 44 on the p⁺-type layer 32. Next, as illustrated in FIG. 14E, the manufacturing apparatus forms the interlayer insulating film 48 on the front surface 10a side of the GaN substrate 10.

Next, as illustrated in FIG. 14F, the manufacturing apparatus partly removes the interlayer insulating film 48, the gate insulating film 42, the p⁺-type layer 32, and the n⁺-type layer 31 in this order by photolithography and etching so as to form contact holes H1 on the contact region 25 and the source region 26. Subsequently, the manufacturing apparatus forms the source electrode 54 (refer to FIG. 6) on the front surface 10a side of the GaN substrate 10 so as to lead the source electrode 54 to be in contact with the n⁺-type source region 26 and the p⁺-type well region 23. Further, the manufacturing apparatus forms the drain electrode 56 (refer to FIG. 6) on the rear surface 10b side of the GaN substrate 10 so as to lead the drain electrode 56 to be in contact with the n⁺-type GaN single-crystal substrate 11. The planar-type vertical MOSFET as illustrated in FIG. 6 is thus completed through the process described above.

### (Modified Example)

(I) The step of forming the n⁺-type layer 31 and the p⁺-type layer 32 illustrated in FIG. 14C may stack the plural n⁺-type layers 31 and p⁺-type layers 32 into several layers through alternate doping of the donor element such as Si, O and Ge and the acceptor element such as Mg by epitaxial growth. FIG. 15 is a graph showing modified example 1 of the manufacturing method according to Embodiment 5. The axis of abscissas in FIG. 15 indicates a depth of the epitaxially-grown layer from the front surface, and the axis of ordinates indicates a concentration of the dopant element, such as a Mg concentration and a Si concentration. As shown in FIG. 15, Si used as the donor element and Mg used as the acceptor element may be alternately doped while the GaN layer is epitaxially grown on the front surface of the GaN substrate. This method can manufacture the planar-gate vertical MOSFET including the plural n⁺-type layers 31 and p⁺-type layers 32 alternately stacked into several layers, as illustrated in FIG. 7. While the concentration of the respective donor and acceptor elements preferably has a steep inclination during the epitaxial growth, the concentration may have an inclination with about several nanometers until keeping constant. Since the outermost front surface preferably has a higher Mg concentration, the concentration that is highest on the front surface side is preferably gradually decreased toward the inner side of the substrate.

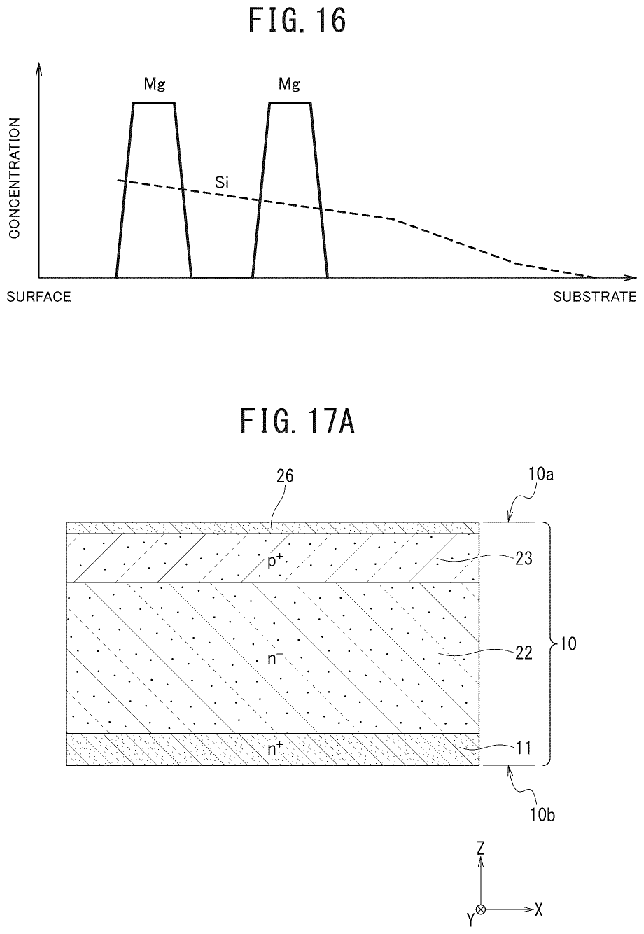

(II) The step of forming the n⁺-type layer 31 and the p⁺-type layer 32 illustrated in FIG. 14C may stack the plural n⁺-type layers 31 and p⁺-type layers 32 into several layers through both doping of the acceptor element such as Mg by epitaxial growth and ion implantation of the donor element such as Si, O and Ge. FIG. 16 is a graph showing modified example 2 of the manufacturing method according to Embodiment 5. The axis of abscissas in FIG. 16 indicates a depth of the epitaxially-grown layer from the front surface, and the axis of ordinates indicates a concentration of the dopant element such as a Mg concentration and a Si concentration. As shown in FIG. 16, Mg may be doped at predetermined intervals while the GaN layer is epitaxially grown on the front surface of the GaN substrate. While the concentration of the respective donor and acceptor elements preferably has a steep inclination during the epitaxial growth, the concentration may have an inclination with about several nanometers until keeping constant. Since the outermost front surface preferably has a higher Mg concentration, the concentration that is highest on the front surface side is preferably gradually decreased toward the inner side of the substrate. Subsequently, Si may be implanted into the front surface side of the GaN layer. Thereafter, the GaN layer is subjected to heat treatment so as to activate Si. This method can also manufacture the planar-gate vertical MOSFET including the plural n⁺-type layers 31 and p⁺-type layers 32 alternately stacked into several layers, as illustrated in FIG. 7.

### Embodiment 6

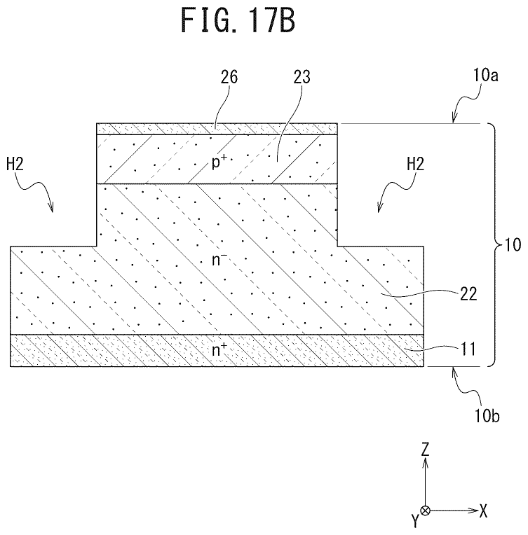

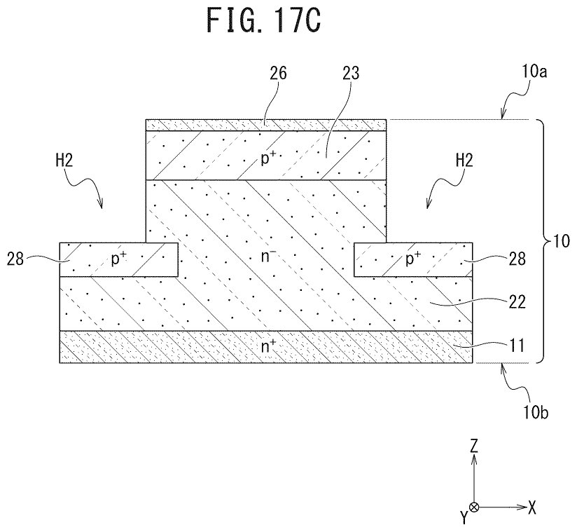

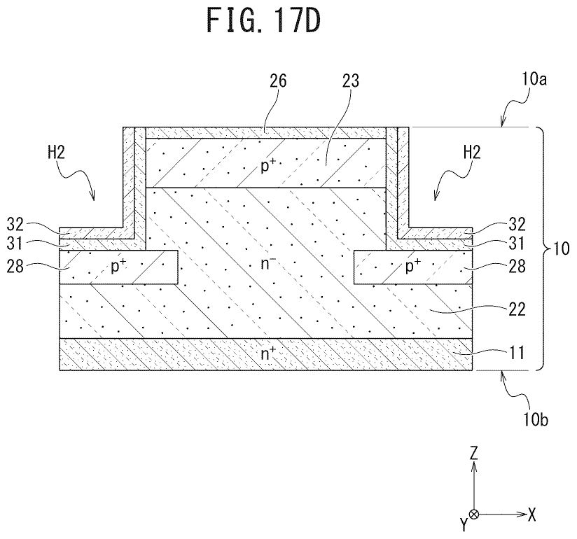

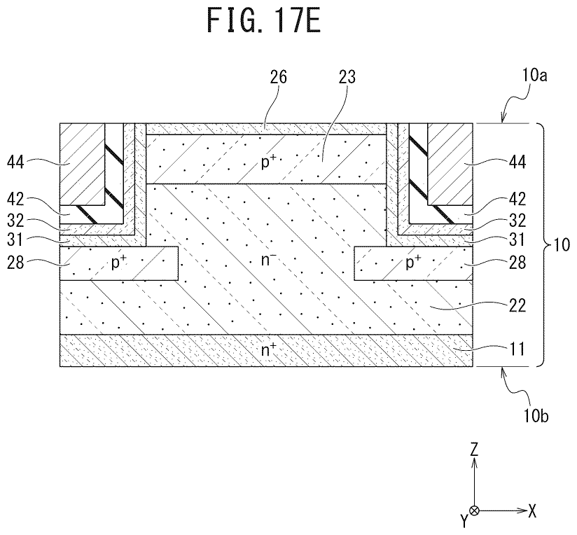

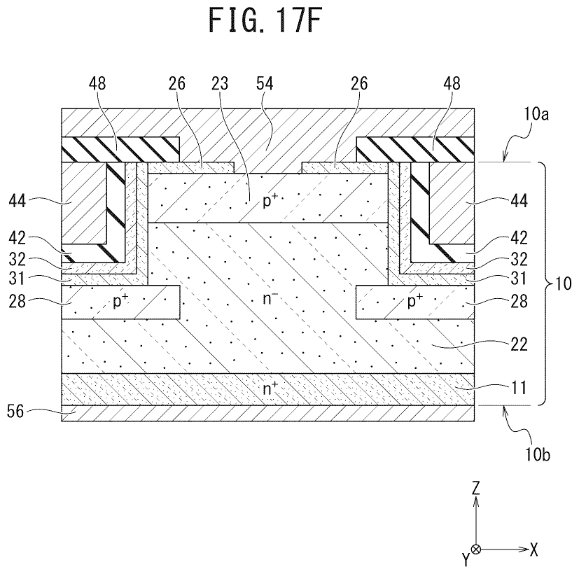

A method of manufacturing a trench-gate vertical MOSFET according to Embodiment 6 of the present disclosure is described below. FIG. 17A to FIG. 17F are cross-sectional views illustrating a sequential process of the method of manufacturing the vertical MOSFET according to Embodiment 6 of the present disclosure. As illustrated in FIG. 17A, the manufacturing apparatus epitaxially grows, on the n⁺-type GaN single-crystal substrate 11, the n-type GaN layer 22, the p⁺-type GaN layer to serve as the p⁺-type well region 23, and the n⁺-type GaN layer to serve as the n⁺-type source region 26 in this order.

Next, as illustrated in FIG. 17B, the manufacturing apparatus partly removes the GaN layer to serve as the source region 26, the GaN layer to serve as the well region 23, and the n-type GaN layer 22 sequentially in this order by photolithography and etching so as to form trenches H2. The provision of the trenches H2 define the p⁺-type well region 23. Next, as illustrated in FIG. 17C, the manufacturing apparatus executes ion implantation of an acceptor element such as Mg into the bottom of the respective trenches H2 and further executes heat treatment so as to form the p⁺-type region 28.

Next, as illustrated in FIG. 17D, the manufacturing apparatus epitaxially grows the n⁺-type layer 31 and the p⁺-type layer 32 in this order on the respective bottom and side surfaces of the trenches H2. The n⁺-type layer 31 and the p⁺-type layer 32 in this case are sequentially epitaxially grown so that the Mg concentration in the p⁺-type layer 32 is in a range of 1×10¹⁸ cm⁻³ or higher and 1×10²⁰ cm⁻³ or lower, preferably in a range of 1×10¹⁹ cm⁻³ or higher and 1×10²⁰ cm⁻³ or lower, and the effective donor concentration Nn (cm⁻³) and the thickness dn (nm) of the n⁺-type layer 31 and the effective acceptor concentration Np (cm⁻³) and the thickness Nn (nm) of the p⁺-type layer 32 fulfill the respective inequalities (1) and (2) described above.

Next, as illustrated in FIG. 17E, the manufacturing apparatus forms the gate insulating film 42 on the respective side and bottom surfaces of the trenches. The manufacturing apparatus then forms the gate electrode 44 inside the trenches provided with the gate insulating film 42. Next, as illustrated in FIG. 17F, the manufacturing apparatus forms the interlayer insulating film 48 on the front surface 10a side of the GaN substrate 10.

Next, the manufacturing apparatus partly removes the interlayer insulating film 48 by photolithography and etching so as to expose the GaN layer serving as the n⁺-type source region 26 from the lower side of the interlayer insulating film 48. Next, the manufacturing apparatus partly removes the GaN layer serving as the n⁺-type source region 26 by photolithography and etching. This step defines the n⁺-type source region 26 and further exposes the p⁺-type well region 23 from the lower side of the n⁺-type source region 26.

Subsequently, the manufacturing apparatus forms the source electrode 54 on the front surface 10a side of the GaN substrate 10 so as to lead the source electrode 54 to be in contact with the n⁺-type source region 26 and the p⁺-type well region 23. Further, the manufacturing apparatus forms the drain electrode 56 on the rear surface 10b side of the GaN substrate 10 so as to lead the drain electrode 56 to be in contact with the n⁺-type GaN single-crystal substrate 11. The trench-gate vertical MOSFET as illustrated in FIG. 8 is thus completed through the process described above.

Modified example (I) or (II) of Embodiment 5 may also be applied to Embodiment 6. In particular, the n⁺-type layer 31 and the p⁺-type layer 32 may be alternately stacked into several layers through alternate doping of the donor element such as Si, O and Ge and the acceptor element such as Mg by epitaxial growth. Alternatively, the n⁺-type layer 31 and the p⁺-type layer 32 may be alternately stacked into several layers through both the doping of the acceptor element such as Mg by epitaxial growth and the ion implantation of the donor element such as Si, O and Ge. This method can also manufacture the trench-gate vertical MOSFET including the plural n⁺-type layers 31 and p⁺-type layers 32 alternately stacked into several layers, as illustrated in FIG. 9.

### Embodiment 7

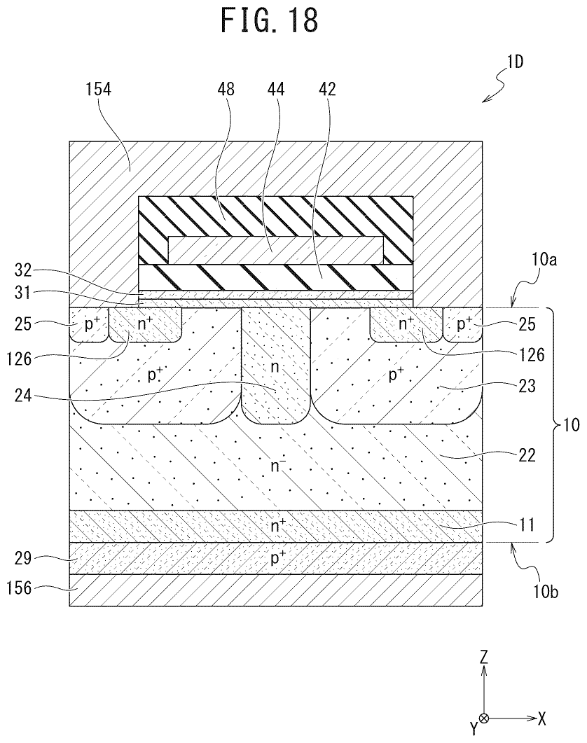

Embodiment 1 is illustrated above with the lateral MOSFET as an example of the “transistor” according to the present disclosure. Embodiments 2 to 4 are illustrated above with the vertical MOSFET as an example of the “transistor” according to the present disclosure. The “transistor” according to the present disclosure is not limited to the MOSFET, and can be an IGBT instead. FIG. 18 is a cross-sectional view illustrating an IGBT 1D having normally-off characteristics according to Embodiment 7 of the present disclosure. As illustrated in FIG. 18, the IGBT 1D is provided in the GaN substrate 10.

The IGBT 1D illustrated in FIG. 18 differs from the vertical MOSFET 1A illustrated in FIG. 6 in including an emitter region 126 of n⁺-type instead of the source region 26, an emitter electrode 154 instead of the source electrode 54, and a collector electrode 156 instead of the drain electrode 56, and further including a collector layer 29 of p⁺-type on the rear surface side of the n⁺-type GaN single-crystal substrate 11 corresponding to the rear surface 10b side of the GaN substrate 10. The other configurations of this embodiment are the same as those of the vertical MOSFET 1A illustrated in FIG. 6.

The emitter region 126 has the same configuration as the source region 26, the emitter electrode 154 has the same configuration as the source electrode 54, and the collector electrode 156 has the same configuration as the drain electrode 56.

The collector layer 29 is a GaN layer of p⁺-type doped with p-type impurities such as Mg. The collector layer 29 is interposed between the n⁺-type GaN single-crystal substrate 11 and the collector electrode 156 so as to be in contact with both the n⁺-type GaN single-crystal substrate 11 and the collector electrode 156. The collector layer 29 may be formed by any method, and can be formed by epitaxial growth on the rear surface of the GaN single-crystal substrate 11, for example.

As in the case of the lateral MOSFET 1 or the vertical MOSFET 1A described above, the IGBT 1D illustrated in FIG. 18 also includes the n⁺-type layer 31 and the p⁺-type layer 32. The p⁺-type layer 32 in the IGBT 1D is also located at a position opposed to the gate electrode 44 with the gate insulating film 42 interposed. The n⁺-type layer 31 is located at a position opposed to the gate electrode 44 with the p⁺-type layer 32 interposed. The n⁺-type layer 31 and the p⁺-type layer 32 are arranged in this order from the well region 23 toward the gate electrode 44, for example.

### (Effects of Embodiment 7)

The Mg concentration in the p⁺-type layer 32 in Embodiment 7 of the present disclosure is also set in the range of 1×10¹⁸ cm⁻³ or higher and 1×10²⁰ cm⁻³ or lower, and preferably in the range of 1×10¹⁹ cm⁻³ or higher and 1×10²⁰ cm⁻³ or lower. The respective inequalities (1) and (2) described above are fulfilled, where the effective acceptor concentration of the p⁺-type layer 32 is Np (cm⁻³), the thickness of the p⁺-type layer 32 is dp (nm), the effective donor concentration of the n⁺-type layer 31 is Nn (cm⁻³), and the thickness of the n⁺-type layer 31 is dn (nm).

This configuration leads the n⁺-type layer 31 to serve as a channel in the IGBT 1D. The n⁺-type layer 31 is completely depleted in the state in which the gate bias is zero volts, so as to exhibit the normally-off characteristics. This can introduce Mg into the interface between the GaN substrate 10 and the gate insulating film 42 at a high concentration while decreasing the threshold of the IGBT 1D to a low level, so as to inactivate a hole-trapping state caused at the interface.

### (Modified Example)

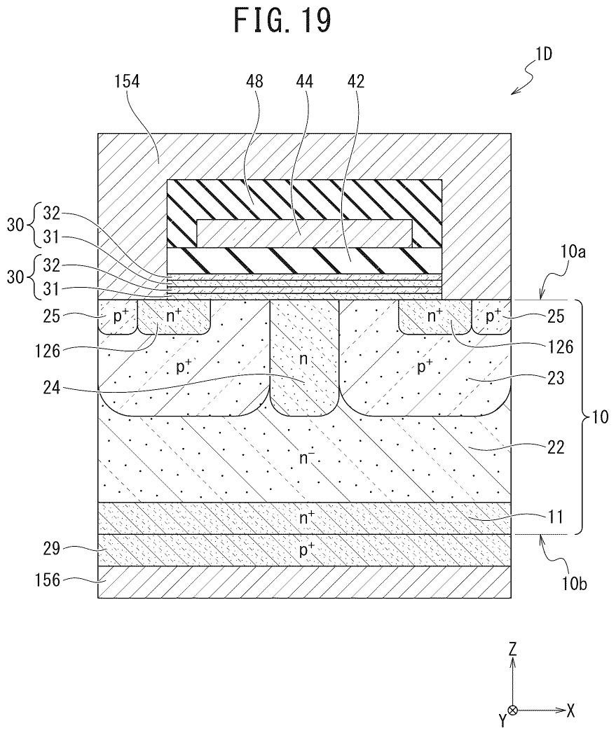

FIG. 19 is a cross-sectional view illustrating a modified example of the IGBT 1D according to Embodiment 7 of the present disclosure. As illustrated in FIG. 19, the IGBT 1D may include plural n⁺-type layers 31 and plural p⁺-type layers 32. For example, in a case in which a set of the n⁺-type layer 31 and the p⁺-type layer 32 is defined as a pair 30, the n-number of the pairs 30 (n is an integer of two or greater) may be arranged to overlap with each other at a position opposed to the gate electrode 44 with the gate insulating film 42 interposed. Namely, the n⁺-type layer 31 and the p⁺-type layer 32 may be alternatively and repeatedly arranged in this order from the well region 23 toward the gate electrode 44. FIG. 19 illustrates the case of including two pairs 30 (n=2) of the n⁺-type layer 31 and the p⁺-type layer 32. The inequalities (1) and (2) described above are also fulfilled in each pair 30 in the modified example illustrated in FIG. 19. The modified example illustrated in FIG. 19 thus can achieve the effects similar to those in Embodiment 7.

The modified examples (II) to (V) of the vertical MOSFET 1A according to Embodiment 2 can also be applied to the IGBT 1D according to Embodiment 7. In such a case, the emitter region 126 is substituted for the source region 26 described in the modified example (IV). Similarly, the emitter electrode 154 is substituted for the source electrode 54 described in the modified example (V).

### OTHER EMBODIMENTS

While the present disclosure has been described above by reference to Embodiments and the respective modified examples, it should be understood that the present disclosure is not intended to limit the descriptions and the drawings composing part of this disclosure. Various alternative embodiments and modified examples will be apparent to those skilled in the art according to this disclosure. For example, the gate insulating film 42 is not limited to the SiO₂ film, but may be any other insulating film determined as appropriate. Examples of insulating films used as the gate insulating film 42 include a silicon oxynitride (SiON) film, a strontium oxide (SrO) film, a silicon nitride (Si₃N₄) film, and an aluminum oxide (Al₂O₃) film. The gate insulating film 42 may also be a composite film including some of the single insulating films stacked on one another.

It should be understood that the present disclosure can include various embodiments not disclosed herein, and can include at least any of omissions, replacements, or modifications of the constitutional elements without departing from the teaching of the respective embodiments and modified examples described above. It should also be understood that the effects described herein are illustrated merely as some examples that are not limited to the above descriptions, and the present disclosure may have other effects not disclosed herein.

The present disclosure can also have the following configurations.

(1) A nitride semiconductor device comprising:
a nitride semiconductor substrate; and
a transistor having a normally-off characteristic provided in the nitride semiconductor substrate,
wherein:
the transistor includes
   a gate insulating film provided on a first surface side of the nitride semiconductor substrate,
   a gate electrode provided on the gate insulating film,
   a p-type layer located to be opposed to the gate electrode with the gate insulating film interposed, and
   an n-type layer located to be opposed to the gate electrode with the p-type layer interposed so as to be in contact with the p-type layer;
a Mg concentration in the p-type layer is in a range of 1×10¹⁸ cm⁻³ or higher and 1×10²⁰ cm⁻³ or lower; and
the above inequations (1) and (2) are fulfilled, where
   an effective acceptor concentration of the p-type layer in which a donor concentration is canceled out of an acceptor concentration is Np (cm⁻³) and a thickness of the p-type layer is dp (nm), and
   an effective donor concentration of the n-type layer in which an acceptor concentration is canceled out of a donor concentration is Nn (cm⁻³) and a thickness of the n-type layer is dn (nm):
      (2) The nitride semiconductor device of above (1), wherein:
the transistor further includes a p-type well region provided in the nitride semiconductor substrate at a position opposed to the gate electrode with the n-type layer interposed so as to be in contact with the n-type layer; and
a Mg concentration in the well region is in a range of 1×10¹⁷ cm⁻³ or higher and 1×10²⁰ cm⁻³ or lower.
   (3) The nitride semiconductor device of the above (1) or (2), wherein, when a set of the p-type layer and the n-type layer is defined as a pair, the device further comprises an n-number of the pairs (n is an integer of two or greater) arranged to overlap with each other at a position opposed to the gate electrode with the gate insulating film interposed.
   (4) The nitride semiconductor device of any one of the above (1) to (3), wherein:
the transistor further includes a source region of n-type provided on the first surface side of the nitride semiconductor substrate, and a source electrode provided on the first surface side so as to be in contact with the source region; and
the n-type layer is in contact with the source region.
   (5) The nitride semiconductor device of any one of the above (1) to (4), wherein:
the nitride semiconductor substrate has a trench provided on the first surface side;
the gate electrode is provided inside the trench with the gate insulating film interposed; and
the p-type layer is located to be opposed to the gate electrode with the gate insulating film interposed along a side surface of the trench.
   (6) The nitride semiconductor device of any one of the above (1) to (5), wherein the following inequation (3) is fulfilled:

$$dp \times Np - dn \times Nn < 1 \times 1 {0}^{18} \times [ dp + dn ] \qquad ( 3 )$$

(7) The nitride semiconductor device of any one of the above (1) to (3) and (5), wherein:
the transistor is an IGBT; and
the transistor further includes
   an emitter layer of n-type provided on the first surface side of the nitride semiconductor substrate,
   an emitter electrode provided on the first surface side so as to be in contact with the emitter layer,
   a collector layer of p-type provided on a second surface side of the nitride semiconductor substrate on an opposite side of the first surface, and
   a collector electrode located at a position opposed to the nitride semiconductor substrate with the collector layer interposed so as to be in contact with the collector layer.
      (8) A nitride semiconductor device comprising:
a nitride semiconductor substrate; and
a transistor having a normally-off characteristic provided in the nitride semiconductor substrate,
wherein:
the transistor includes
   a gate insulating film provided on a first surface side of the nitride semiconductor substrate,
   a gate electrode provided on the gate insulating film,
   a p-type layer located to be opposed to the gate electrode with the gate insulating film interposed, and
   an n-type layer located to be opposed to the gate electrode with the p-type layer interposed so as to be in contact with the p-type layer;
a Mg concentration in the p-type layer is in a range of 1×10¹⁸ cm⁻³ or higher and 1×10²⁰ cm⁻³ or lower; and
the n-type layer is completely depleted in a state in which a bias toward the gate electrode is zero volts.
   (9) The nitride semiconductor device of any one of the above (1) to (8), wherein the Mg concentration in the p-type layer is in a range of 1×10¹⁹ cm⁻³ or higher and 1×10²⁰ cm⁻³ or lower.

What is claimed is:

1. A nitride semiconductor device comprising:
a nitride semiconductor substrate; and
a transistor having a normally-off characteristic provided in the nitride semiconductor substrate,
wherein:
the transistor includes
a gate insulating film provided on a first surface side of the nitride semiconductor substrate,
a gate electrode provided on the gate insulating film,
a p-type layer located to be opposed to the gate electrode with the gate insulating film interposed, and
an n-type layer located to be opposed to the gate electrode with the p-type layer interposed so as to be in contact with the p-type layer;
a Mg concentration in the p-type layer is in a range of 1×10¹⁸ cm⁻³ or higher and 1×10²⁰ cm⁻³ or lower; and
the following inequations (1) and (2) are fulfilled, where
an effective acceptor concentration of the p-type layer in which a donor concentration is canceled out of an acceptor concentration is Np (cm⁻³) and a thickness of the p-type layer is dp (nm), and
an effective donor concentration of the n-type layer in which an acceptor concentration is canceled out of a donor concentration is Nn (cm⁻³) and a thickness of the n-type layer is dn (nm):
$$[ Math . 1 ]$$
$$3 nm < {d}_{n} ( nm ) < 1.16 \times {10}^{11} \sqrt{\frac{{N}_{p}}{( {N}_{n} + {N}_{p} ) {N}_{n}}} \qquad ( 1 )$$
$$3 nm < {d}_{p} ( nm ) < 5.78 \times {10}^{10} \sqrt{\frac{{N}_{n}}{( {N}_{n} + {N}_{p} ) {N}_{p}}} . \qquad ( 2 )$$

2. The nitride semiconductor device of claim 1, wherein:
the transistor further includes a p-type well region provided in the nitride semiconductor substrate at a position opposed to the gate electrode with the n-type layer interposed so as to be in contact with the n-type layer; and
a Mg concentration in the well region is in a range of 1×10¹⁷ cm⁻³ or higher and 1×10²⁰ cm⁻³ or lower.

3. The nitride semiconductor device of claim 1, wherein, when a set of the p-type layer and the n-type layer is defined as a pair, the device further comprises an n-number of the pairs (n is an integer of two or greater) arranged to overlap with each other at a position opposed to the gate electrode with the gate insulating film interposed.

4. The nitride semiconductor device of claim 1, wherein:
the transistor further includes a source region of n-type provided on the first surface side of the nitride semiconductor substrate, and a source electrode provided on the first surface side so as to be in contact with the source region; and
the n-type layer is in contact with the source region.

5. The nitride semiconductor device of claim 1, wherein:
the nitride semiconductor substrate has a trench provided on the first surface side;
the gate electrode is provided inside the trench with the gate insulating film interposed; and
the p-type layer is located to be opposed to the gate electrode with the gate insulating film interposed along a side surface of the trench.

6. The nitride semiconductor device of claim 1, wherein the following inequation (3) is fulfilled:
$$dp \times Np - dn \times Nn < 1 \times 1 {0}^{18} \times [ dp + dn ] . \qquad ( 3 )$$

7. The nitride semiconductor device of claim 1, wherein:
the transistor is an IGBT; and
the transistor further includes
an emitter layer of n-type provided on the first surface side of the nitride semiconductor substrate,
an emitter electrode provided on the first surface side so as to be in contact with the emitter layer,
a collector layer of p-type provided on a second surface side of the nitride semiconductor substrate on an opposite side of the first surface, and
a collector electrode located at a position opposed to the nitride semiconductor substrate with the collector layer interposed so as to be in contact with the collector layer.

8. A nitride semiconductor device comprising:
a nitride semiconductor substrate; and
a transistor having a normally-off characteristic provided in the nitride semiconductor substrate,
wherein:
the transistor includes
a gate insulating film provided on a first surface side of the nitride semiconductor substrate,
a gate electrode provided on the gate insulating film,
a p-type layer located to be opposed to the gate electrode with the gate insulating film interposed, and
an n-type layer located to be opposed to the gate electrode with the p-type layer interposed so as to be in contact with the p-type layer;
a Mg concentration in the p-type layer is in a range of 1×10¹⁸ cm⁻³ or higher and 1×10²⁰ cm⁻³ or lower; and
the n-type layer is completely depleted in a state in which a bias toward the gate electrode is zero volts.

9. The nitride semiconductor device of claim 1, wherein the Mg concentration in the p-type layer is in a range of 1×10¹⁹ cm⁻³ or higher and 1×10²⁰ cm⁻³ or lower.

10. The nitride semiconductor device of claim 8, wherein the Mg concentration in the p-type layer is in a range of 1×10¹⁹ cm⁻³ or higher and 1×10²⁰ cm⁻³ or lower.
